(19) United States
(12) Patent Application Publication
(10) Pub. No.: US 2026/0190282 A1
(43) Pub. Date: Jul. 2, 2026

(54) FLUID, SYSTEM AND METHOD FOR IMMERSION COOLING OBJECTS HAVING PLASTICIZED SURFACES

(71) Applicant: ADVANCING CHEMISTRY INC., Calgary (CA)

(72) Inventor: Shaun MESHER, Calgary (CA)

(21) Appl. No.: 19/549,881

(22) Filed: Feb. 25, 2026

Related U.S. Application Data
(63) Continuation of application No. 18/109,176, filed on Feb. 13, 2023, now Pat. No. 12,581,616.
(60) Provisional application No. 63/309,870, filed on Feb. 14, 2022.

(51) Int. Cl. H05K 7/20; C09K 5/20; G06F 1/20

(52) U.S. Cl. CPC H05K 7/20236; C09K 5/20; G06F 1/20; H05K 7/20272

(57) ABSTRACT

A cooling fluid comprising a coolant for immersion cooling an object therein, the object comprising a plasticized surface and a plasticizer dispersed in the coolant, the plasticizer being diffusible into the plasticized surface of the object when the object is in contact with the coolant, wherein a weight ratio of the plasticizer to the coolant in the cooling fluid is at least 0.005.

### CROSS-REFERENCE TO RELATED APPLICATIONS

This application is a Continuation of U.S. patent application Ser. No. 18/109,176 filed on Feb. 13, 2023. This application also claims the benefit of U.S. Provisional Patent Application Ser. No. 63/309,870 filed on Feb. 14, 2022. The contents of the aforementioned applications are incorporated by reference herein.

### FIELD

The present disclosure relates generally to cooling fluids, systems and methods, and specifically to fluids, systems and methods for immersion cooling objects having plasticized surfaces.

### BACKGROUND

It is often desirable or necessary to cool electronic devices, which can generate heat during operation. Coolants have been used to cool heat-generating objects in a cooling technique known as immersion cooling.

For example, computing devices including entire computer servers and electronic storage devices may be submerged in a thermally conductive dielectric coolant in liquid immersion cooling for various applications, including mining of cryptocurrencies such as Bitcoin. The cooling fluid is in direct contact with the hot computing devices and components and absorbs heat from the computing devices and components and may be itself then be cooled in a heat exchanger and recirculated. In mining operations, the mining computers operate at high clock speeds for extended periods of time, and the operating temperature of the cooling fluid may be as high as 60° C.

It has been observed that some components of the computing systems immersed in the coolant will degrade during immersion cooling much faster than, for example, in an air-cooled environment. For example, connection cables and wires in the computing system often became less pliable and their outer layers became split and crack over time.

It is thus desirable to provide improved immersion cooling techniques and immersion cooling liquids to reduce degradation of such components.

### SUMMARY

In an embodiment, the present disclosure relates to a cooling fluid that comprises a coolant for immersion cooling an object therein, the object comprising a plasticized surface. The cooling fluid also comprises a plasticizer dispersed in the coolant, the plasticizer being diffusible into the plasticized surface of the object when the object is in contact with the coolant, wherein a weight ratio of the plasticizer to the coolant in the cooling fluid is at least 0.005.

In some embodiments, the plasticizer is the same as a plasticizer in the plasticized surface of the object.

In some embodiments, the concentration of the plasticizer in the cooling fluid is the same or higher than a concentration of the plasticizer in the plasticized surface of the object.

In some embodiments, the plasticizer comprises a low molecular weight ortho-phthalate, a high molecular weight ortho-phthalate, a terephthalate, a trimellitate, an aliphatic, a benzoate, a phosphate, or a polymeric plasticizer.

In some embodiments, the low molecular weight ortho-phthalate comprises butyl benzyl phthalate (BBP), dimethyl phthalate (DMP) diethyl phthalate (DEP), diisobutyl phthalate (DIBP), dihexyl phthalate (DHP), di-n-butyl phthalate (DBP), dicyclohexyl phthalate (DCHP), di(2-ethylhexyl) phthalate (DEHP) or di(2-propylheptyl) phthalate (DPHP).

In some embodiments, the concentration of the plasticizer in the cooling fluid is 0.5 wt % to 20 wt % based on a total weight of the cooling fluid. In some embodiments, the concentration of the plasticizer in the cooling fluid is 5 wt % to 15 wt %.

In some embodiments, the coolant comprises an oil.

In some embodiments, the coolant has a density of between 0.800 and 1.100 kg/L at 15° C.

In another embodiment, the present disclosure relates to a cooling system comprising a container comprising a chamber for receiving therein an object to be cooled and the cooling fluid as defined herein in the chamber for immersing the object in the cooling fluid.

In some embodiments, the object comprises a computing device.

In another embodiment, the present disclosure relates to a method of cooling an object comprising a plasticized surface. The method comprises immersing the object in the cooling fluid as defined herein, wherein the plasticized surface is in contact with the cooling fluid.

In some embodiments, the plasticized surface of the object comprises a plasticized polymer.

In some embodiments, the object comprises a computing device.

In some embodiments, the computing device is immersion cooled in the cooling fluid at a temperature of at least 50° C. for at least 30 days.

In another embodiment, the present disclosure relates to a method of forming a cooling fluid for immersion cooling an object, wherein the object comprises a plasticized polymer. The method comprises selecting and providing a coolant suitable for immersion cooling the object and mixing the coolant with a plasticizer to form a mixture, wherein the plasticizer is diffusible into the plasticized polymer when the object is immersed in the mixture.

In another embodiment, the present disclosure relates to the use of a plasticizer in a cooling fluid comprising a coolant for immersion cooling an object having a plasticized surface.

In another embodiment, the present disclosure relates to the use of a cooling fluid as described herein for immersion cooling an object having a plasticized surface.

### BRIEF DESCRIPTION OF THE DRAWINGS

In the figures, which illustrate example embodiments:

FIG. 1 is a schematic block diagram of a cooling system for immersion cooling one or more objects, according to an example embodiment of the present disclosure;

FIG. 2 is a photograph of a cord;

FIGS. 3A and 3B are photographs of a cord after being immersed in a comparison fluid for 30 days (FIG. 3A) and 120 days (FIG. 3B) respectively;

FIGS. 4A and 4B are photographs of a cord after being immersed in a cooling fluid according to an embodiment of the present disclosure for 30 days (FIG. 4A) and 120 days (FIG. 4B) respectively;

FIGS. 5A and 5B are photographs of a cord after being immersed in a cooling fluid according to an embodiment of the present disclosure for 30 days (FIG. 5A) and 120 days (FIG. 5B) respectively;

FIGS. 6A and 6B are photographs of a cord after being immersed in a cooling fluid according to an embodiment of the present disclosure for 30 days (FIG. 6A) and 120 days (FIG. 6B) respectively;

FIGS. 7A-C are photographs of a cord after being immersed in another comparison fluid for 40 days (FIG. 7A), 117 days (FIG. 7B) and 419 days (FIG. 7C) respectively;

FIGS. 8A-C are photographs of a cord after being immersed in another comparison fluid for 40 days (FIG. 8A), 117 days (FIG. 8B) and 419 days (FIG. 8C) respectively;

FIGS. 9A-C are photographs of a cord after being immersed in another comparison fluid for 40 days (FIG. 9A), 117 days (FIG. 9B) and 419 days (FIG. 9C) respectively;

FIGS. 10A-C are photographs of a cord after being immersed in another comparison fluid for 40 days (FIG. 10A), 117 days (FIG. 10B) and 419 days (FIG. 10C) respectively;

FIGS. 11A-C are photographs of a cord after being immersed in another comparison fluid for 40 days (FIG. 11A), 117 days (FIG. 11B) and 293 days (FIG. 11C) respectively;

FIGS. 12A-C are photographs of a cord after being immersed in another comparison fluid for 40 days (FIG. 12A), 117 days (FIG. 12B) and 293 days (FIG. 12C) respectively;

FIGS. 13A-C are photographs of a cord after being immersed in another comparison fluid for 40 days (FIG. 13A), 117 days (FIG. 13B) and 293 days (FIG. 13C) respectively;

FIGS. 14A-C are photographs of a cord after being immersed in another comparison fluid for 40 days (FIG. 14A), 117 days (FIG. 14B) and 293 days (FIG. 14C) respectively;

FIGS. 15A and 15B are photographs of a cord after being immersed in a cooling fluid according to an embodiment of the present disclosure for 40 days (FIG. 15A) and 251 days (FIG. 15B) respectively;

FIGS. 16A and 16B are photographs of a cord after being immersed in a cooling fluid according to an embodiment of the present disclosure for 40 days (FIG. 16A) and 251 days (FIG. 16B) respectively;

FIGS. 17A and 17B are photographs of a cord after being immersed in a cooling fluid according to an embodiment of the present disclosure for 40 days (FIG. 17A) and 251 days (FIG. 17B) respectively;

FIGS. 18A and 18B are photographs of a cord after being immersed in a cooling fluid according to an embodiment of the present disclosure for 40 days (FIG. 18A) and 251 days (FIG. 18B) respectively;

FIGS. 19A and 19B are photographs of a cord after being immersed in a cooling fluid according to an embodiment of the present disclosure for 40 days (FIG. 19A) and 169 days (FIG. 19B) respectively;

FIGS. 20A and 20B are photographs of a cord after being immersed in a cooling fluid according to an embodiment of the present disclosure for 40 days (FIG. 20A) and 169 days (FIG. 20B) respectively;

FIGS. 21A and 21B are photographs of a cord after being immersed in a cooling fluid according to an embodiment of the present disclosure for 40 days (FIG. 21A) and 169 days (FIG. 21B) respectively;

FIGS. 22A and 22B are photographs of a cord after being immersed in a cooling fluid according to an embodiment of the present disclosure for 40 days (FIG. 22A) and 169 days (FIG. 22B) respectively;

FIGS. 23A and 23B are photographs of a cord after being immersed in a cooling fluid according to an embodiment of the present disclosure for 40 days (FIG. 23A) and 187 days (FIG. 23B) respectively;

FIGS. 24A and 24B are photographs of a cord after being immersed in a cooling fluid according to an embodiment of the present disclosure for 40 days (FIG. 24A) and 187 days (FIG. 24B) respectively;

FIGS. 25A-C are photographs of a cord after being immersed in a cooling fluid according to an embodiment of the present disclosure for 40 days (FIG. 25A) and 187 days (FIGS. 25B and 25C) respectively;

FIGS. 26A and 26B are photographs of a cord after being immersed in a cooling fluid according to an embodiment of the present disclosure for 40 days (FIG. 26A) and 187 days (FIG. 26B) respectively;

FIGS. 27A and 27B are photographs of a cord after being immersed in a cooling fluid according to an embodiment of the present disclosure for 40 days (FIG. 27A) and 169 days (FIG. 27B) respectively;

FIGS. 28A and 28B are photographs of a cord after being immersed in a cooling fluid according to an embodiment of the present disclosure for 40 days (FIG. 28A) and 169 days (FIG. 28B) respectively;

FIGS. 29A and 29B are photographs of a cord after being immersed in a cooling fluid according to an embodiment of the present disclosure for 40 days (FIG. 29A) and 169 days (FIG. 29B) respectively; and

FIGS. 30A and 30B are photographs of a cord after being immersed in a cooling fluid according to an embodiment of the present disclosure for 40 days (FIG. 30A) and 169 days (FIG. 30B) respectively;

### DETAILED DESCRIPTION

It has been recognized that when computing components, such as wires and cables, with plastic surface layers are in contact with a cooling fluid at elevated temperatures for an extended period of time, degradation due to loss of plasticity can occur faster than in normal conditions or in an air-cooled environment. Without being limited to any specific theory, the present inventor has realized that such accelerated loss of plasticity can result from leaching of plasticizers from the plastic surface layers into the cooling liquid due to increased diffusion of the plasticizer molecules at higher temperatures. The present inventor has also discovered that such loss of plasticity can be reduced or prevented if a suitable plasticizer is added to the coolant. It is thus desirable to provide a cooling fluid that includes a coolant and a plasticizer dispersed in the coolant such that the added plasticizer is diffusible into the plasticized surface of the computing components at the operation conditions, to reduce or even prevent the net loss of plasticizers from the cooled plasticized surface.

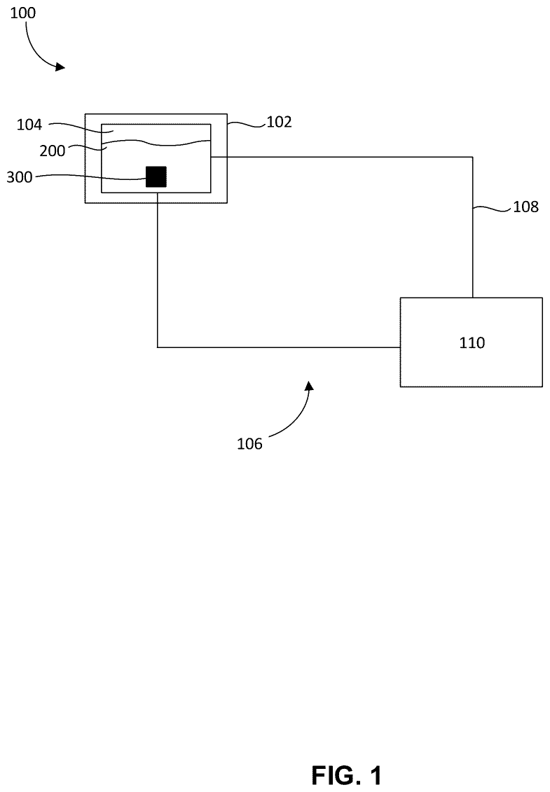

It may be expected that by reducing or preventing the loss of plasticizers from the cooled plasticizer surface, the loss of plasticity is also reduced or prevented. This in turn may reduce degradation of the computing components, such as by preventing splitting of cracking cause by the reduction in plasticity. In an example embodiment, a cooling system 100 for immersion cooling one or more objects is schematically illustrated in FIG. 1.

System 100 includes a container 102 having a chamber 104, and a cooling fluid 200 contained in the chamber 104. Chamber 104 also houses one or more objects 300 therein. Objects 300 are immersed in cooling liquid 200. Container 102 may be a closed container (e.g., a container with a resealable lid) which may reduce or prevent evaporation of cooling liquid 200 from chamber 104 during operation. In another embodiment, container 102 is an open container.

The system 100 also includes fluid circulation circuit 106, which includes a heat exchanger 110 and one or more conduits 108 connecting the heat exchanger 110 to the container 102 for circulating and cooling the cooling liquid 200. Fluid circulation circuit 106 is typically a closed fluid circuit.

The cooling fluid 200 includes a coolant and a plasticizer. The coolant may preferably be a fluid having high thermal conductivity and no or low electrical conductivity (i.e., an electric insulator such a dielectric fluid).

The coolant in the cooling liquid 200 is selected for immersion cooling particular objects, such as electronic or computing devices and components. Depending on the types of the objects 300 to be cooled and the particular application of immersion cooling, the coolant may be readily selected by those skilled in the art from known coolants. For example, for computer mining operations, typical coolants may include dielectric fluids, such as a perfluorinated compounds, a polyalphaolefin (PAO) fluid, an aliphatic fluid, an aromatic fluid, or a silicone oil.

The coolant may be a hydrocarbon fluid, such as a blend of one or more aliphatic and aromatic fluids which include hydrocarbons ranging from C₁₀-C₅₀. An aliphatic hydrocarbon in an aliphatic fluid may be a straight or branched chain alkane or olefin. The aliphatic fluid may include butane, pentane, cyclopentane, hexane, cylcohexane, heptane, octane, nonane, decane, undecane, or dodecane. An aliphatic solvent may also be used, which may be any suitable blend of more than one aliphatic solvents such as gasoline, diesel, petroleum distillate, petroleum ether, mineral spirits, naptha, mineral oil, kerosene, or turpentine. The aliphatic fluid may be a synthetic aliphatic fluid such as a polyalphaolefin (PAO)

The coolant may be group II, II+, III, IV or V base oil or a blend of more than one group II, II+, III, IV or V base oils.

The coolant may be made from a renewable source, such as an ester of a vegetable oil.

The coolant may include a hydrotreated petroleum distillate, such as Neutral Oil 60R sold by Chevron.

The coolant may have a density of between about 0.800 and about 1.100 kilograms/litre (kg/L) at 15° C.

The coolant may have a flash point greater than about 93° C., as measured by the American Society for Testing and Materials (ASTM) D93 standard test method. The flash point may be greater than about 150° C.

The coolant may have a viscosity index (VI) between about 60 and about 300.

The coolant may be an oil with a viscosity of about 1 mPa·s. at 40° C. The use of a low viscosity oil as the coolant may be beneficial as lower viscosity fluids will flow faster under the same physical conditions, thereby removing heat faster from the immersed object.

The oil may be substantially free of preservatives and antioxidants, because such additives could contribute to the emulsification of water from the atmosphere with the coolant, especially over a prolonged period of time at elevated temperatures. Including water in the cooling fluid is undesirable because water emulsified with the coolant oil can reduce the efficiency of the coolant and can also lead to corrosion of some immersed objects.

In the cooling fluid, a plasticizer is dispersed in the coolant. As used herein, a plasticizer refers to a substance that has been added to another material to increase the plasticity of the other material, or render the other material softer and more flexible. Plasticizers are typically organic compounds that are added to polymeric materials such as plastic and rubber to improve the plasticity and flexibility of the material. Depending on the types of the objects 300 to be cooled and the coolant selected, the plasticizer may be readily selected by those skilled in the art from known plasticizers.

In the cooling liquid, the plasticizer is selected and dispersed in a manner that allows the molecules of the plasticizer to diffuse in the cooling liquid and into a plasticized surface that is in contact with the cooling liquid.

The concentration of the plasticizer in the cooling liquid 200 should be high enough so it is sufficient to reduce or prevent net loss of plasticizer from the plasticized surfaces of objects 300 that are in contact with the cooling liquid 200. For example, the weight ratio of the plasticizer to the coolant in the cooling fluid 200 may be at least 0.005, such as from 0.005 to about 0.2, from 0.005 to about 0.1, or from about 0.05 to about 0.1.

The concentration of the plasticizer in the cooling fluid may be the same as, or higher than, the concentration of the plasticizer(s) in the plastic components to be cooled.

According to an embodiment, the weight ratio of the plasticizer to the coolant in the cooling fluid is at least 0.005. In other embodiments, the weight ratio of the plasticizer to the coolant in the cooling fluid is at least 0.01, or at least 0.02, or at least 0.04, or at least 0.06, or at least 0.08, or at least 0.10, or at least 0.12, or at least 0.14, or at least 0.16, or at least 0.18, or at least 0.20.

For some applications, the cooling fluid may contain at least about 0.5 wt % plasticizer, based on the total weight of cooling fluid for example, at least about 2 wt % plasticizer, at least about 4 wt % plasticizer, at least about 6 wt % plasticizer, at least about 8 wt % plasticizer, at least about 10 wt % plasticizer, at least about 12 wt % plasticizer, at least about 14 wt % plasticizer, at least about 16 wt % plasticizer, at least about 18 wt % plasticizer, or at least about 20 wt % plasticizer based on the total weight of the cooling fluid.

The plasticizer may include one or more of: a low molecular weight ortho-phthalate, a high molecular weight ortho-phthalate, a terephthalate, a trimellitate, an aliphatic, a benzoate, a phosphate, or a polymeric plasticizer.

The plasticizer may be a low Molecular weight ortho-phthalate (i.e., those having alkyl chains of 1 to 6 carbon atoms in length) for example, butyl benzyl phthalate (BBP), dimethyl phthalate (DMP) diethyl phthalate (DEP), diisobutyl phthalate (DIBP), dihexyl phthalate (DHP), di-n-butyl phthalate (DBP), dicyclohexyl phthalate (DCHP), di(2-ethylhexyl) phthalate (DEHP) or di(2-propylheptyl) phthalate (DPHP).

The plasticizer may also be a high Molecular weight (C₇+) ortho-phthalate (i.e., those having alkyl chains of 7 or more carbon atoms in length) such as, for example: diisoheptyl phthalate, dicapryl phthalate (DCP), diisooctyl phthalate, diisononyl phthalate (DIDP), diisodecyl phthalate (DIDP), diisoundecyl phthalate (DIUP), diundecyl phthalate (DUP) or ditridecyl phthalate (DTDP).

The plasticizer may be a terephthalate such as, for example: dibutyl terephthalate (DBT), di-tert-butyl terephthalate (DTP), bis(2 ethyl hexylterephthalate) (DEHT) or dioctyl terephthalate (DOTP).

The plasticizer may be a trimellitate such as, for example: tri-(2-ethylhexyl) trimellitate (TEH™), triisononyl trimellitate (TIN™), tri-isodecyl trimellitate (TID™), triisotridecyl trimellitate (TITD™), trioctyl mellitate (TO™), triisononyl trimellitate (TIO™), tricapryl trimellitate or tri (n-octyl, n-decyl) trimellitate (NOD™)

Aliphatic plasticizers may include, adipates, sebacates, azelates, cyclohexanoates and citrates.

The plasticizer may be an adipate, such as, for example: diisobutyl adipate, di(2-ethylhexyl) adipate (DEHA), dicapryl adipate (DCA), di(n-heptyl, n-nonyl) adipate, diisononyl adipate (DINA), diisodecyl adipate (DIDA), or ditridecyl adipate (DTDA).

The plasticizer may be a sebacate, such as, for example: di-methyl sebacate (DMS). dibutyl sebacate (DBS), di-(2-ethylhexyl) sebacate or di-octyl debacate (DOS).

The plasticizer may be an azelate, such as, for example: Dimethyl azelate, di-n-hexyl azelate (DNHZ), di(2-ethylhexyl) azelate (DOZ), diisooctyl azelate (DOA) or diisodecyl azelate.

The plasticizer may be a cyclohexanoate such as, for example: 1,2-cyclohexane dicarboxylic acid diisononyl ester (DINCH) or di-octyl cyclohexanoate (DOCH).

The plasticizer may be a citrate, such as, for example: Triethyl citrate (TEC), acetyltributyl citrate (ATBC) or tributyl citrate (ATBC).

The plasticizer may be a benzoate such as, for example: isononyl benzoate (INB), isodecyl benzoate (IDB), diethylene glycol dibenzoate, dipropylene glycol dibenzoate, neopentyl glycol dibenzoate or tri-ethylene glycol dibenzoate.

The plasticizer may be a phosphate, such as, for example: tris(2-ethylhexyl) phosphate, 2-ethylhexyl diphenyl phosphate, tricresyl(methyl phenyl) phosphate (TCP) or tributyl phosphate (TBP).

The plasticizer may be a polymeric plasticizer such as, for example: a polyester of an aliphatic dicarboxylic acid, such as (hexanedioic acid, polymer with 2,2-dimethyl-1,3-propanediol and 1,2-propanediol, isononyl ester), (hexanedioic acid, polymer with 1,2-propanediol, octyl ester) or (hexanedioic acid, polymer with 1,2-propanediol, acetate).

The object(s) 300 may be any device having one or more heat-generating components that may require cooling. When an object 300 has at least one plasticized surface that is exposed and in contact with the cooling liquid during immersion cooling, cooling liquid 200 may be beneficially used. For example, the object may be an electronic device, or components of an electronic device, such as a computing system or a server.

The objects 300 may include exposed plasticized surfaces, such as plastic cover layers on wires, cables, and other plastic components.

The plasticized surface of object 300 may be the surface of other components of an electronic device, such as connectors, capacitors, structural components (i.e., mounting brackets, frames) and o-rings. Such components may be manufactured from acrylonitrile butadiene styrene (ABS), high impact polystyrene (HIPS), polycarbonate and polyethylene terephthalate (PET).

In an embodiment, the object 300 may include a cable, which is submerged in the cooling fluid 200. Such cables may include one or more conductive cores, encased in a plastic coating. The plastic coating may be made be made, for example, from polyvinyl chloride (PVC), polyethylene, cross-linked polyethylene, polypropylene, ethylene chlorotrifluorethylene (ETCFE), Nylon and polyvinylidene fluoride (PVDF).

As is well known, di(2-ethylhexyl) phthalate (DEHP) is commonly added to PVC. The amount of plasticizer in the plastic may affect the plasticity and flexibility of the plastic. For example, a reduction in the plasticizer concentration in the plastic may undesirably cause the polymeric material to become more brittle, and prone to splitting or cracking which may lead to decreased performance or even failure.

When a PVC material is in contact with a coolant, the plasticizer in the PVC material may be leached out of the PVC material. Without being limited to any particular theory, it is expected that when the PVC material is immersed in a coolant without any added plasticizer, there will be net diffusion of the plasticizer from areas of relatively high plasticizer concentration in the PVC material to an area of relatively low plasticizer concentration in the coolant. The net effect of the molecular diffusion may be removal or loss of a substantial portion of the plasticizer originally contained in PVC material.

By providing a cooling fluid 200 with a plasticizer dispersed within the cooling fluid, the net loss of the plasticizer from the PVC or other plasticized surfaces, may be reduced or prevented as the concentration of plasticizer in the cooling fluid is increased. Through preventing loss of plasticizer from the plasticized surface, splitting or cracking of plastic components may be prevented and the plastic will maintain its plasticity and flexibility.

For example, if the concentration of the plasticizer in the cooling fluid 200 is sufficiently high, such as being higher than the initial concentration of the plasticizer in the plasticized surface of the objects 300, net loss of plasticizer from the cooled object 300 may be prevented. Even at a lower added plasticizer concentration, the net loss of plasticizer from the cooled object 300 may still be reduced as the diffusion rate of the plasticizer towards the cooling fluid 200 is still reduced due to the decreased concentration gradient. Further, the concentration gradient may even be reversed, i.e., the cooling fluid 200 has a relatively high plasticizer concentration and the plasticized surface has a relatively low plasticizer concentration, such that more plasticizer may diffuse into the plasticized surface from the cooling fluid 200. This reverse concentration gradient may provide replacement or replenishment of the plasticizer in the plasticized surface.

The plasticizer dispersed in the coolant may be selected from plasticizers that are typically added to polymers for altering the properties of the plastic materials formed from the polymers. A suitable plasticizer is dispersible within the coolant such that the plasticizer is available for diffusion into the plasticized surface of the object when the object is in contact with the coolant. The plasticizer may be partially or fully miscible with the coolant such that they form a homogenous mixture. The plasticizer and the coolant may be in separate phases, with the plasticizer evenly dispersed within the coolant. The plasticizer and the coolant may form an emulsion.

In an embodiment, the plasticizer in the plasticized surface of the object is the same as the plasticizer dispersed in the coolant. For example, the plasticized surface may be the outer surface of a PVC coated cable, such as an ethernet cable. The PVC may include DEHP as a plasticizer and the cooling fluid may also include DEHP dispersed within the coolant.

In some applications, the plasticized surface of the cooled objects may contain a mixture of more than one plasticizer and the cooling fluid 200 may also include a mixture of the same plasticizers dispersed in the coolant.

The concentration of the plasticizer in the cooling fluid 200 may be the same or higher as the concentration of the plasticizer in the plasticized surface of the object 300. For example, where the plasticized surface is the outer surface of a PVC coated cable and the PVC has a plasticizer concentration of 10 wt %, based on the total weight of the PVC, the cooling fluid may have 10 wt % or greater that 10 wt % plasticizer dispersed in the coolant based on the total weight of the cooling fluid.

The cooling fluid 200 may be prepared by any suitable method. For example, a coolant suitable for immersion cooling the particular object(s) to be cooled may be selected based on a number of known factors, such as the anticipated temperature of the cooling fluid when cooling the object(s), the materials of the object(s) that will be exposed to the cooling fluid and the anticipated lifespan of the cooling fluid (i.e., the run time before replacement of the cooling fluid).

A suitable plasticizer and target concentration range of the plasticizer in the final liquid are also selected and determined, depending on the particular objects to be cooled. For example, the plasticizer may be selected based on factors such as the plasticizers(s) in the object(s) to be cooled, the anticipated temperature of the cooling fluid when cooling the object(s), the anticipated lifespan of the cooling fluid (i.e., the run time before replacement of the cooling fluid) and the compatibility of the plasticizer with the selected coolant at the selected target concentration range

The target concentration range of the plasticizer may be selected based on factors such as the surface area of plasticized surface of the objects(s) that is exposed to the cooling fluid and the concentration of plasticizer(s) within the plastic components of the object(s) to be cooled.

The selected coolant and plasticizer may be mixed by any suitable method to form a mixture. The mixture is prepared in such a way that at least some of the plasticizer molecules in the liquid mixture are free to move or diffuse through the liquid so that the plasticizer is diffusible into an object in contact with or immersed in the liquid mixture.

During immersion cooling, the cooling fluid 200 may partially or fully immerse the object 300 to be cooled in the container 102.

Object 300 may include a computer, or heat generating components of a computer. Such components may include application specific integrated circuits (ASICs) or graphics processing units (GPUs).

As can be appreciated, by reducing or preventing net loss of plasticiser from the plasticized surface, the plasticity and flexibility of the plastic surface material can be maintained at a desired level for a longer period of time.

For example, computing components may be immersed in cooling fluid 200 for longer periods of time and/or at higher temperatures whilst the plasticity and flexibility of plastic components is maintained at a desired level. This will beneficially reduce splitting and cracking and may increase life span of plastic components, which in turn reduces downtime caused by maintenance and component failure

The cooling fluids of the present disclosure may be used in computer mining, where it is desirable run computers at a high clock rate, that is at a rate exceeding that certified by the manufacturer. This will further increase the heat generated by the computer. Furthermore, multiple computers may be placed in close proximity to one another, further increasing the heat generated. By providing a cooling fluid as described herein for immersion cooling one or more computers, the computers can be run at a high clock rate for prolonged periods or time whilst the degradation of plastic components that are immersed in the cooling fluid is reduced or prevented.

### Example 1A (Comparison)

A low-density polyethylene (PE-LD) cord was submerged in DRILLSOL™ Plus at 50-75° C. for 120 days.

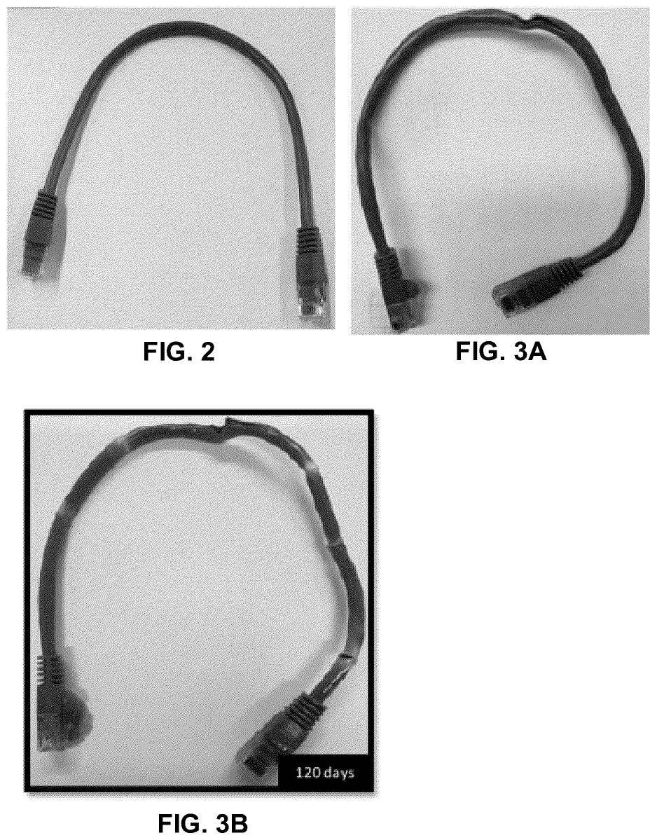

A photograph of the cord before immersion is shown in FIG. 2.

After the immersion period, the cord was taken out and bent, and immediately snapped upon bending and a large area of the cord became exposed. The cord was also very stiff and difficult to bend. A photograph of the cord after being immersed in DRILLSOL™ Plus for 30 days and after bending is shown in FIG. 3A. A photograph of the cord after being immersed in DRILLSOL™ Plus for 120 days is shown in FIG. 3B.

### Example 1B

Each low-density polyethylene cord (PE-LD) cord was submerged in a sample cooling solution containing DRILLSOL Plus as the coolant and di(2-ethylhexyl) phthalate (DEHP) as the plasticizer at 50-75° C. for 120 days. The sample cooling solutions tested were: (A) 1.0 v/v % di(2-ethylhexyl) phthalate in DRILLSOL Plus; (B) 5.0 v/v % di(2-ethylhexyl) phthalate in DRILLSOL Plus; and (C) 10.0 v/v % di(2-ethylhexyl) phthalate in DRILLSOL Plus.

Samples A, B, and C were prepared by adding 4.5 mL, 22.5 mL, and 45.0 mL of DEHP to sufficient DRILLSOL Plus to provide a total volume of 450 mL. Each mixture was vigorously shaken until the solution appeared homogeneous.

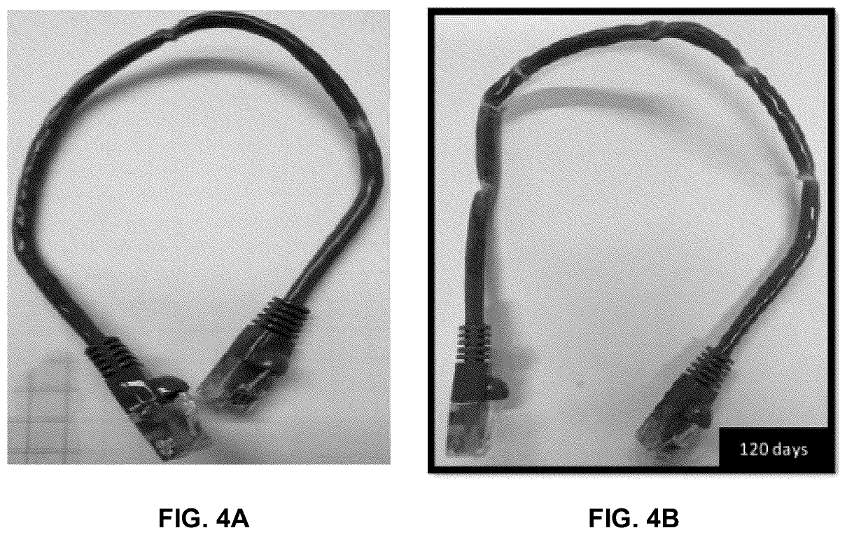

The samples were then transferred to glass jars and a test cord was submerged in each mixture before each jar was covered. Each jar was placed in a water bath between a temperature of 50-75° C. for 120 days. The cords were observed visually and physically examined. Photographs of the cords immersed in Samples A, B, C after 30 days are shown in FIGS. 4A, 5A, 6A. Photographs of the cords immersed in Samples A, B, C after 120 days are shown in FIGS. 4B, 5B and 6B. Observations of these samples and the Comparison Sample are listed in Table 1.

TABLE 1

| | Observations at Specified Loading of Plasticizer | | | |
|---|---|---|---|---|
| Time | Comparison | Sample A | Sample B | Sample C |
| (days) | Sample (0 v/v %) | (1.0 v/v %) | (5.0 v/v %) | (10.0 v/v %) |
| 30 | The cord was | Cord was relatively | Cord was | Cord was still quite |
| | very stiff and hard | hard to bend. A | relatively difficult | stiff but not as hard |
| | to bend. When | small amount of | to bend though | to bend as the |
| | bent, the cord | cracking was | no snapping was | former cords. No |
| | snapped, thereby | visible near the | visible. A few | matter how many |
| | exposing quite a | bottom of the cord | indents were left | times it was bent, |
| | bit of the wire. | after bending it. | on the cord after | the cord did not |
| | | Bending left a lot of | bending. | snap. |
| | | lasting indents. | | |
| 120 | The cord is | The cord is still | The cord is less | Cord is still |
| | extremely stiff and | extremely hard to | stiff than the | relatively stiff but |
| | difficult to bend. | bend and is very | former and easier | less so than the |
| | When the cord | stiff. However, no | to bend but it was | former. Cord is the |
| | was bent, more of | more cracking had | still quite difficult | easiest to bend of |
| | the wire became | been observed | to bend. Lots of | the bunch and |
| | exposed. There | when bent more. | visible indents/ | there was no |
| | are a lot of marks | More indents did | marks but no | cracking seen |
| | where | occur where the | cracking or | when repeatedly |
| | the cord was bent | cord was newly | exposing of the | bended. There are |
| | previously. | bent. | wire seen. | less indents/ |
| | | | | marks than the |
| | | | | former. |

It was observed that when 1.0 v/v % of DEHP had been added to the DRILLSOL Plus (Sample A), cracking was minimal but still present. The cord was still relatively difficult to bend, but not as tough as for the Comparison Sample. When bending, the cord had numerous lasting indents (FIG. 4A) in which one of them left a tiny crack.

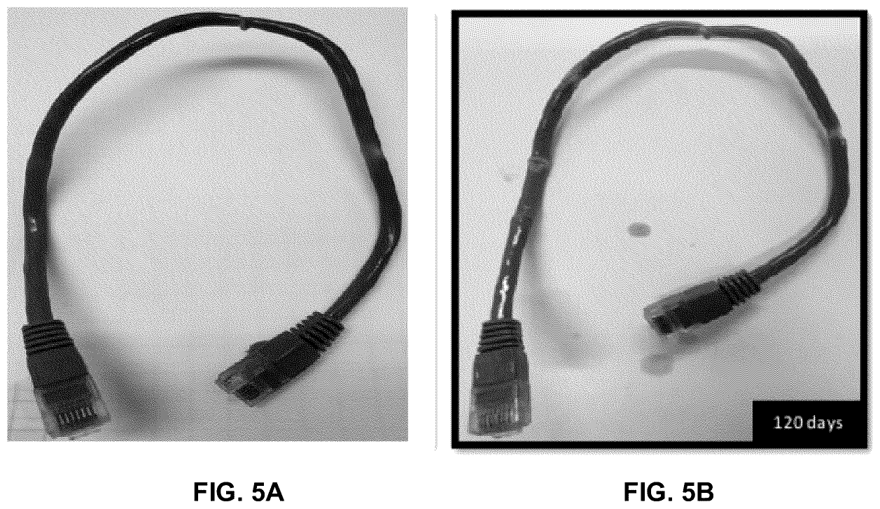

With Sample B (5.0 v/v % of DEHP added to the DRILLSOL Plus), the cord was still relatively difficult to bend though no snapping or cracks were visible after continuous bending (FIG. 5A).

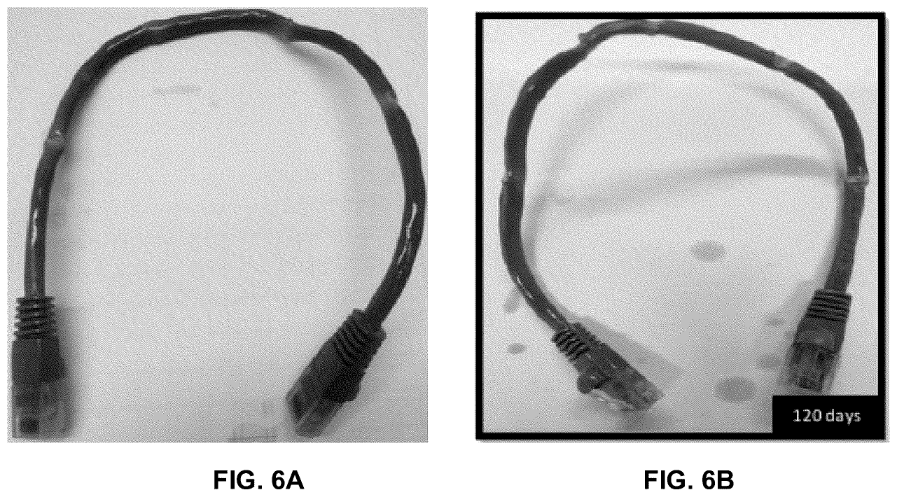

With Sample C (10.0 v/v % DEHP in DRILLSOL Plus), however, had outperformed the former mixtures. The higher concentration of plasticizer allowed the cord to remain in better shape for a longer period by helping the cord to remain relatively flexible. The cord was the easiest to bend, though still difficult and the plasticizer prevented the cord from snapping or cracking when continually bent (FIG. 6A).

It was observed that, in general, deterioration of the cords lessened as a greater amount of DEHP was added to the DRILLSOL Plus.

### Example 2A (Comparison)

A low-density polyethylene (PE-LD) cord was submerged in Chevron Neutral Oil 60R at 55-60° C. for 419 days.

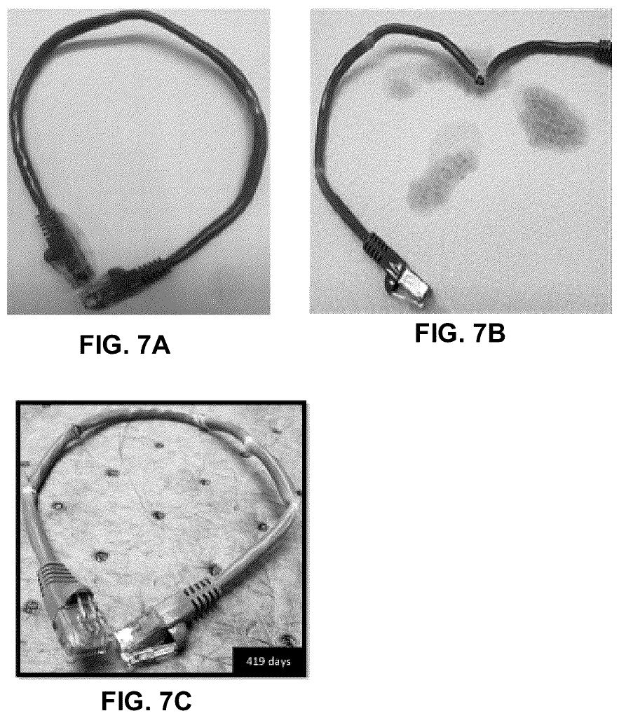

After an immersion period of 40 days, the cord was taken out and bent and did not show any signs of cracking or deterioration, though the cord did become stiffer. A photograph of the cord after bending is shown in FIG. 7A.

After an immersion period of 117 days, the cord was taken out and cracked when bent, as shown in FIG. 7B.

### Example 2B

Each low-density polyethylene cord (PE-LD) cord was submerged in a sample cooling solution containing Chevron Neutral Oil 60R as the coolant and di(2-ethylhexyl) phthalate (DEHP) as the plasticizer at 55-60° C. for 419 days. The sample cooling solutions tested were: (A) 0.5 v/v % di(2-ethylhexyl) phthalate in Chevron Neutral Oil 60R; (B) 1.0 v/v % di(2-ethylhexyl) phthalate in Chevron Neutral Oil 60R; (C) 5.0 v/v % di(2-ethylhexyl) phthalate in Chevron Neutral Oil 60R; (D) 8.0 v/v % di(2-ethylhexyl) phthalate in Chevron Neutral Oil 60R; (E) 10.0 v/v % di(2-ethylhexyl) phthalate in Chevron Neutral Oil 60R; (F) 12.0 v/v % di(2-ethylhexyl) phthalate in Chevron Neutral Oil 60R and (G) 15.0 v/v % di(2-ethylhexyl) phthalate in Chevron Neutral Oil 60R.

Samples A, B, C, D, E, F, G were prepared by adding 2.25-mL, 4.5-mL, 22.5-mL, 36-mL, 45-mL, 54-mL, and 67.5-mL of DEHP to sufficient Chevron Neutral Oil 60R to provide a total volume of 450 mL. Each mixture was vigorously shaken until the solution appeared homogeneous.

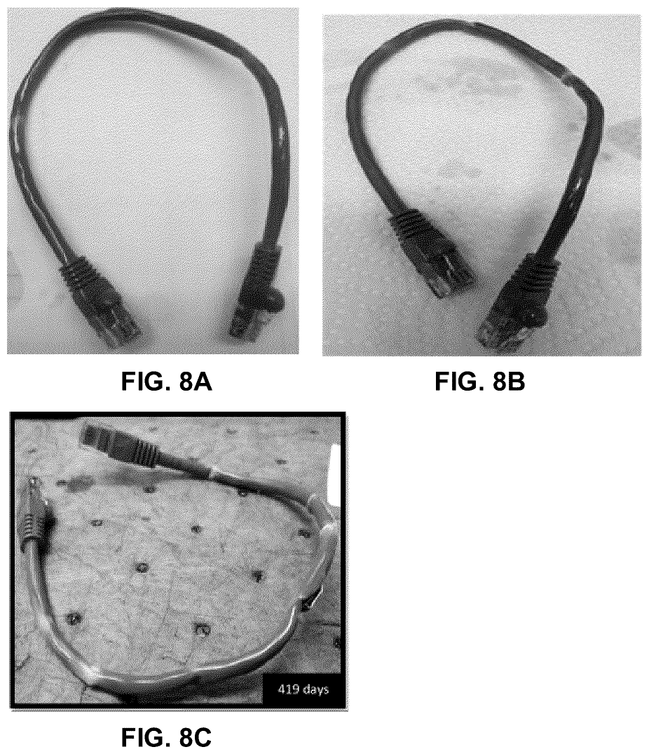

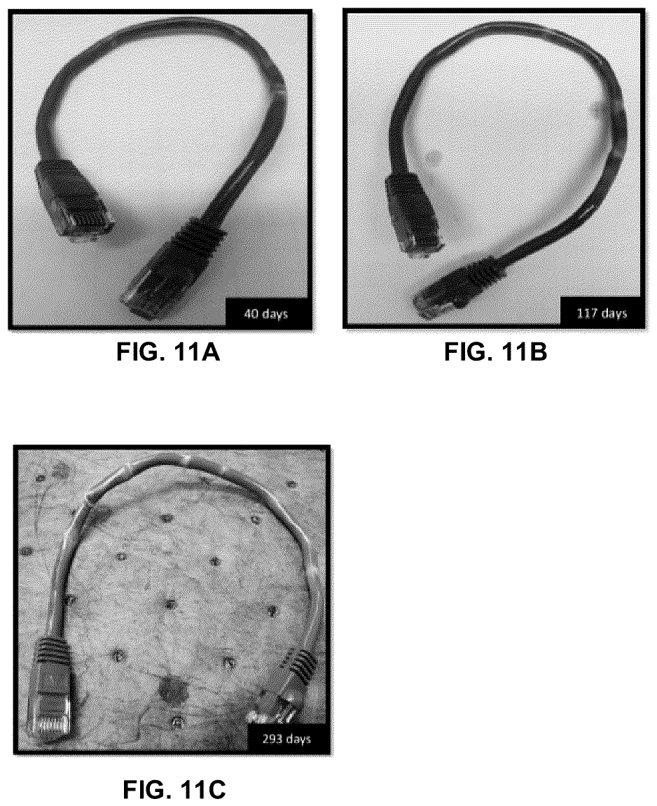

The samples were then transferred to glass jars and a test cord was submerged in each mixture before each jar was covered. Each jar was placed in a water bath between a temperature of 55-60° C. for varying periods of time. The cords were observed visually and physically examined. Photographs of the cords after immersion in Samples A, B, C, D, E, F and G for 40 days are shown in FIGS. 8A, 9A, 10A, 11A, 12A, 13A and 14A respectively. Photographs of the cords after immersion in Samples A, B, C, D, E, F and G for 117 days are shown in FIGS. 8B, 9B, 10B, 11B, 12B, 13B and 14B respectively. Photographs of the cords after immersion in Samples A, B and C for 419 days are shown in FIGS. 8C, 9C and 10C respectively. Photographs of the cords after immersion in Samples D, E, F and G for 293 days are shown in FIGS. 11C, 12C, 13C and 14C respectively. Observations of these samples and the Comparison Sample (Example 2A) are listed in Tables 2 and 3.

TABLE 2

| | Observations at Specified Loading of Plasticizer | | | |
|---|---|---|---|---|
| Time | Comparison | Sample A | Sample B | Sample C |
| (days) | Sample (0 v/v %) | (0.5 v/v %) | (1.0 v/v %) | (5.0 v/v %) |
| 10 | A bit more difficult | Cord was still | Cord was still | Cord was still |
| | to bend the cord | easily bent. | easily bent. | easily bent. |
| | but no cracking is | | | There was no |
| | visible. | | | distinct |
| | | | | difference |
| | | | | between 0.5- |
| | | | | 5.0% at this |
| | | | | point. |
| 17 | Still quite easy to | Cord is more | Cord was the | Cord was still |
| | bend though more | easily bent than | easiest to bend; | easy to bend; |
| | difficult than | the former (the | more easily bent | about the same |
| | before. | Comparison | than the 0.5%. | as 1.0%. |
| | | Sample). | | |
| 21 | A bit stiffer but not | Cord was easier | Cord was similar | Cord was similar |
| | difficult to bend. | to bend than the | to that in 0.5% | to both 0.5% |
| | | Comparison | plasticizer. | and 1.0%. |
| | | Sample. | | |
| 28 | Cord was stiffer | Easier to bend | Easier to bend | Easier to bend |
| | than before. | than the former. | than 0.5%. | than 1.0%. |
| 35 | Cord was stiffer; a | No distinct | No distinct | Cord was still |
| | lot tougher to bend. | change. | change. | the easiest to |
| | | | | bend. |
| 40 | Cord was | Cord was still | Cord was still | Cord was still |
| | moderately difficult | relatively soft. It | easily bent/ | the easiest to |
| | to bend but still | was more easily | bendable. Cord | bend. |
| | does not snap or | bent than the | doesn't indent as | Indentations are |
| | crack open. | Comparison | bad as the former | the least |
| | Bending left slight | Sample and | two after being | noticeable and |
| | indents and cord is | doesn't indent as | bent. Cord was a | cord was the |
| | quite wrinkled. | bad. Cord was a | bit wrinkly. | least wrinkled. |
| | | bit wrinkly. | | |
| 117 | The cord was | Cord was | Cord is still quite | Cord is the least |
| | extremely difficult | relatively difficult | difficult to bend | stiff and is still |
| | to bend. After | to bend though | but there were no | relatively easy to |
| | bending the cord, | not as tough as | visible rips/tears | bend. No rips or |
| | some of the wire | the Comparison | or exposing of the | tears in the cord |
| | had become | Sample. No rips | wires after | after repeatedly |
| | exposed. | or tears in the | bending multiple | bending. |
| | | cord after | times. | |
| | | bending. | | |
| 419 | The cord is very | The cord Is very | The cord is quite | The cord is |
| | stiff and difficult to | stiff and difficult to | wrinkly and stiff | about as stiff as |
| | bend. More rips | bend. Cord ripped | yet is more easily | the 1.0%. The |
| | and tears visible on | when being bent, | bent than the | cord ripped/ |
| | the cord. | thereby exposing | former two. Lots | cracked open |
| | | wires. Lots of | of indents from | when bending, |
| | | indentations after | bending but no | thereby |
| | | bending. | visible rips or | exposing wires. |
| | | | tears. | Lots of indents |
| | | | | from bending |

TABLE 3

| | Observations at Specified Loading of Plasticizer | | | |
|---|---|---|---|---|
| Time | Sample D | Sample E | Sample F | Sample G |
| (days) | (8.0 v/v %) | (10.0 v/v %) | (12.0 v/v %) | (15.0 v/v %) |
| 10 | Cord is very easily | Cord is very | Cord is very | Cord is very |
| | bent. It is very | easily bent. Cord | easily bent. | easily bent. |
| | flexible, and no | is very flexible | Cord is flexible | Cord is flexible |
| | marks/indents | and bounces | and bounces | and bounces |
| | were made when | back after being | back after being | back after being |
| | bending. | bent. | bent. | bent. |
| 17 | Cord is still very | Cord is still very | Cord is still very | Cord is the |
| | flexible and easy | flexible and easy | flexible and easy | easiest to bend |
| | to bend. Minimal | to bend. Minimal | to bend. Minimal | and is the most |
| | markings made | markings made | markings made | flexible. The |
| | when bent (just a | when bent (just a | when bent (just a | least |
| | white | white | white | discoloration is |
| | discoloration, no | discoloration, no | discoloration, no | seen on the |
| | indents made). | indents made). | indents made). | cord when bent. |
| 21 | Cord is still easily | Cord is still | Cord is still | Cord is still |
| | bent. | easily bent. | easily bent. | easily bent; the |
| | | | | most flexible of |
| | | | | the bunch. |
| 28 | The cord is still | The cord is still | The cord is still | The cord is still |
| | very easily bent. | very easily bent. | very easily bent. | very easily bent, |
| | | | Cord is a lot | and it is still the |
| | | | more flexible | most flexible of |
| | | | than 8-10%. | the bunch. |
| 35 | The cord is | No distinct | No distinct | No distinct |
| | starting to get a | change. | change. | change. |
| | bit stiff. | | | |
| 40 | The cord is a bit | The cord is a lot | The cord Is still | The cord is not |
| | stiff, but it is still | more flexible | very flexible, and | stiff at all and is |
| | easy to bend it. No | than 8% and is | no wrinkling of | still the most |
| | cracking is visible | very easily bent. | the cord can be | flexible. Cord is |
| | after repeatedly | A small amount | seen. Very little | quite flimsy and |
| | bending. A small | of wrinkling is | indentations | easy to bend. |
| | amount of | visible on the | made after | No wrinkling of |
| | wrinkling is visible. | cord. | bending the | the cord can be |
| | | | cord. No | seen, and the |
| | | | cracking is seen. | least |
| | | | | indentation |
| | | | | seen after |
| | | | | bending |
| | | | | repeatedly. |
| 117 | Cord is quite stiff | Cord is fairly | Cord is a bit stiff | Cord is the |
| | and difficult to | stiff and fairly | and a lot easier to | easiest to bend |
| | bend. No | difficult to bend | bend than the | and is still |
| | exposed wires or | though easier | former. Indents | slightly flexible. |
| | cracking visible | than the former. | are seen after | No wires are |
| | after repeatedly | No exposed | bending but no | exposed nor is |
| | bending. | wires or | cracking or wires | cracking visible. |
| | | cracking seen | visible. | The least |
| | | after repeated | | indentations are |
| | | bending. | | seen after |
| | | | | bending. |
| 293 | Cord is quite stiff | The cord has | The cord Is a bit | The cord Is the |
| | but relatively | the same | stiffer than the | least stiff, still |
| | easy to bend. | degree of | former, but it is | very easily bent |
| | There are no rips | flexibility as the | still bendable. No | and is very |
| | or tears | 8.0% DEHP. | rips or tears after | flexible. There |
| | after bending | There is no | bending though a | are no cracks or |
| | though there are | ripping or | lot of indentations | tears after |
| | indentations. | tearing after | where bent. | bending. Only a |
| | | bending, though | | few minor |
| | | there are some | | indents seen |
| | | indents where | | after being bent. |
| | | bent. | | |

With Sample A (0.5 v/v % of DEHP added to the Chevron Neutral Oil 60R), it was observed that the cord was a bit softer and easier to bend than the Comparison Sample (FIGS. 8A-C). The cord submerged in Sample A was also less wrinkled than the Comparison Sample.

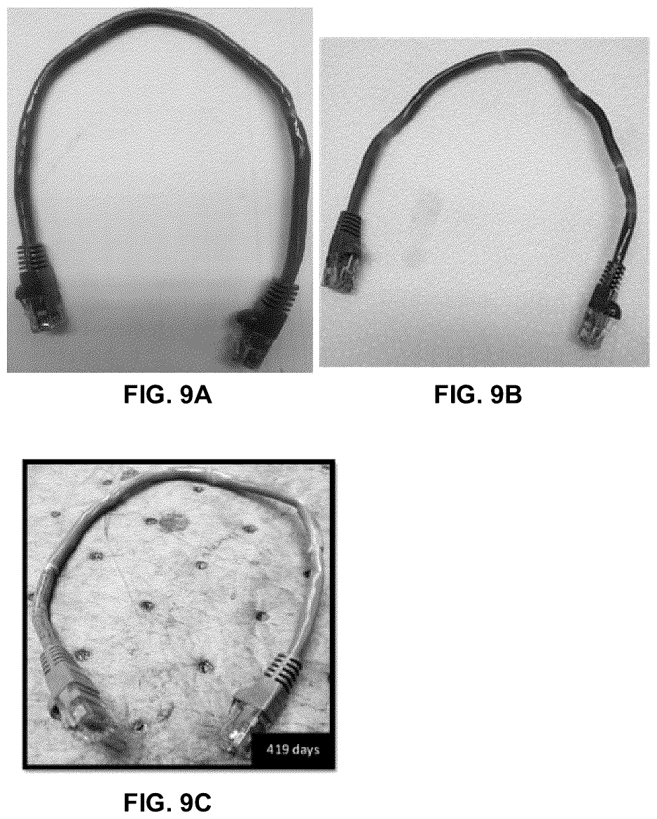

With Sample B (1.0 v/v % of DEHP added to the Chevron Neutral Oil 60R), the cord was very similar to cord submerged in Sample A. The cord had very similar flexibility to the cord submerged in Sample A, had faint indentations after being bent and was only slightly wrinkled (FIGS. 9A-C).

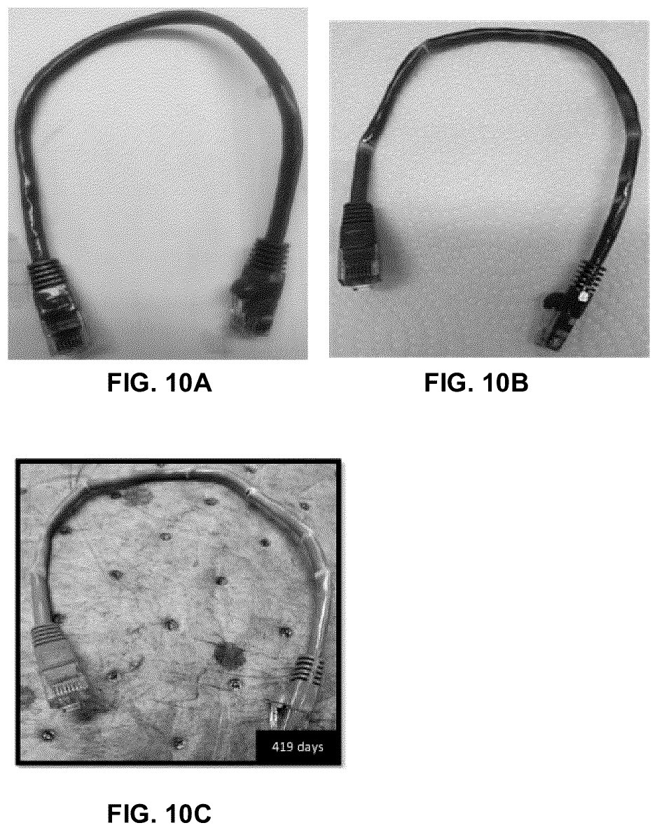

With Sample C (5.0 v/v % DEHP in Chevron Neutral Oil 60R), the cord did not have any indentations after bending and it was the easiest to bend when compared to the Sample A and B cords. Of samples A-C it was the most flexible after being submerged for both 40 and 177-days and was the least wrinkled. There was also no indication of cracking or snapping (FIGS. 10A-C).

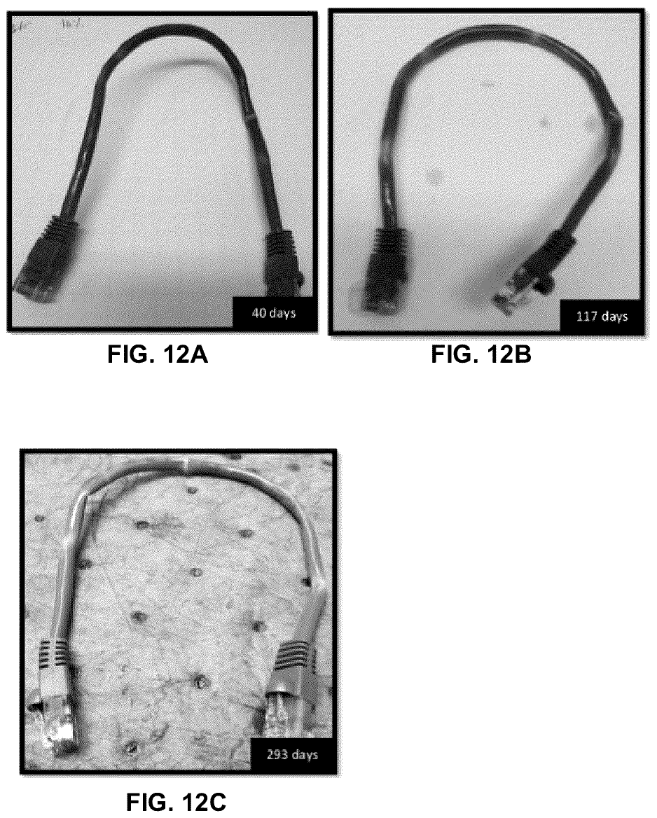

Samples D and E (8.0 v/v % DEHP, FIGS. 11A-C and 10.0 v/v % DEHP Chevron Neutral Oil 60R, FIGS. 12A-C) were quite similar. With Sample D, the cord was a bit less flexible than cord in sample E entering into the second month, they both were quite stiff and quite difficult to bend when observed at both 117 days (˜3 months) and 293 days (<10 months). However, no cracking or rips were observed.

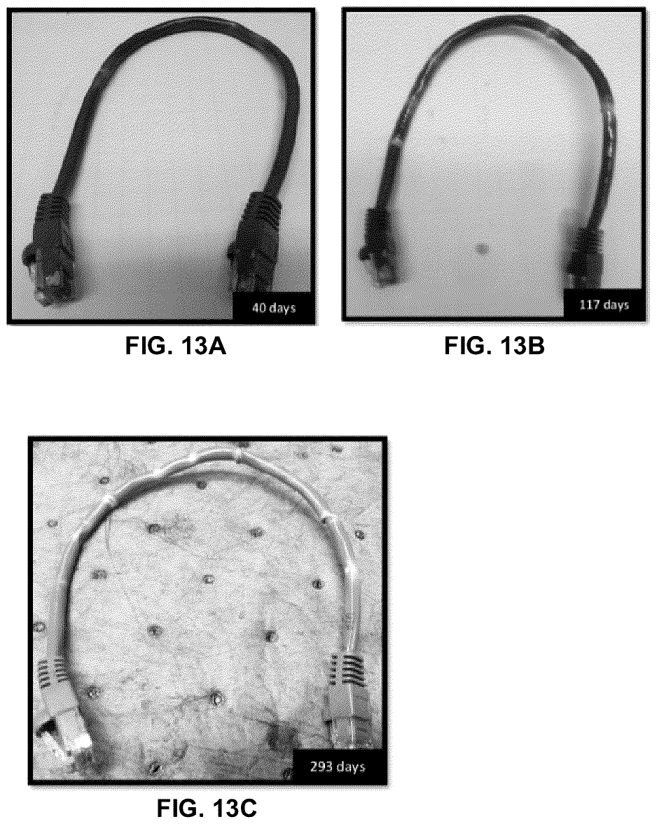

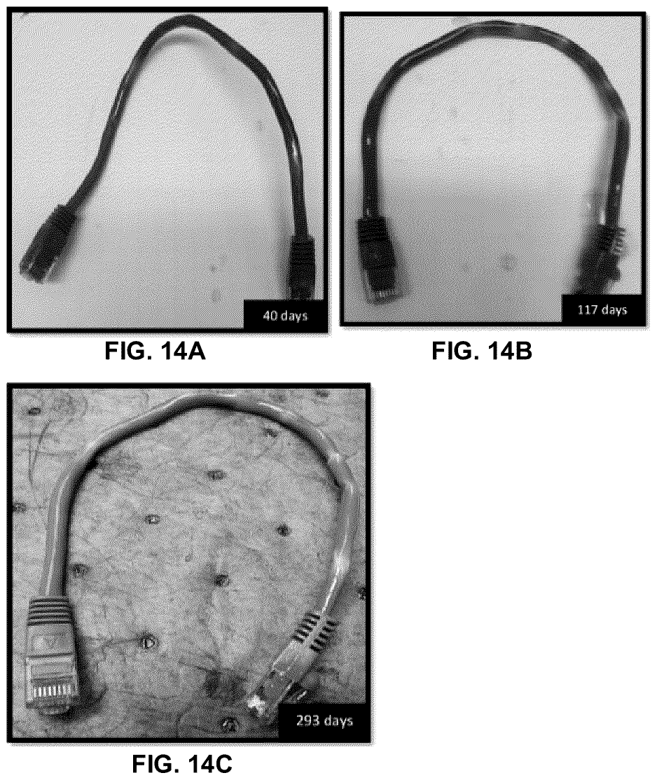

Sample G (15.0 v/v % DEHP in Chevron Neutral Oil 60R, FIGS. 14A-C) was a slight improvement from the cord submerged in Sample G (12.0 v/v % DEHP in Chevron Neutral Oil 60R, FIGS. 13A-C). The higher concentration of plasticizer allowed the cord to remain in better shape for a longer period by helping the cord remain flexible and easy to bend. Less indentations were left behind with sample G was used as opposed to the sample F. No cracking or rips were observed to date.

It was observed that, in general, deterioration of the cords lessened as a greater amount of DEHP was added to the Chevron Neutral Oil 60R.

### Example 3A (Comparison)

A low-density polyethylene (PE-LD) cord was submerged in Bitcool™ at 55-60° C. for 251 days.

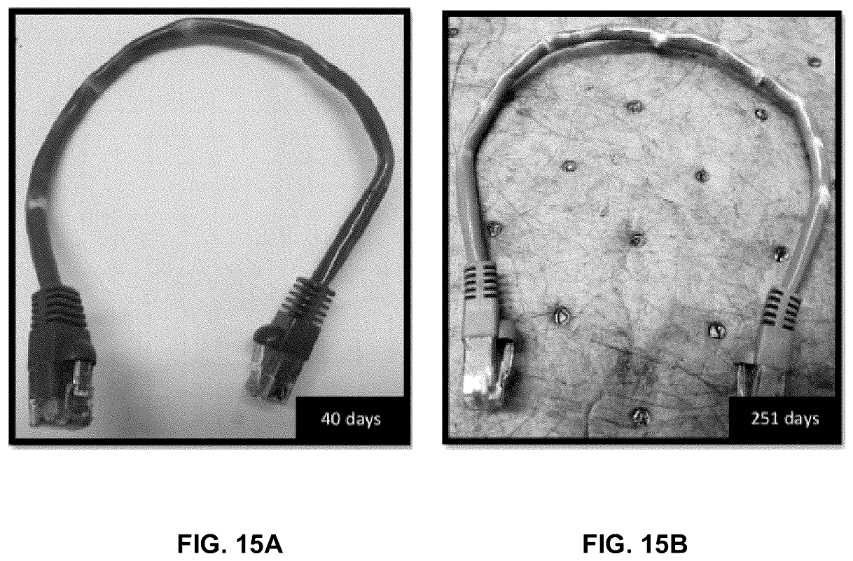

After an immersion period of 40 days, the cord was taken out and bent and the cord remained intact and did not have any cracks when continually bent (FIG. 15A. While the cord was stiff and relatively difficult to bend, it outperformed the Chevron Neutral Oil 60R (see example 2A). After 251 days, the cord was not noticeably cracked (FIG. 15B)

### Example 3B

Each low-density polyethylene cord (PE-LD) cord was submerged in a sample cooling solution containing Bitcool™ as the coolant and di(2-ethylhexyl) phthalate (DEHP) as the plasticizer at 55-60° C. for 251 days. The sample cooling solutions tested were: (A) 5.0 v/v % di(2-ethylhexyl) phthalate in Bitcool™; (B) 10.0 v/v % di(2-ethylhexyl) phthalate in Bitcool™ and (C) 15.0 v/v % di(2-ethylhexyl) phthalate in Bitcool™.

Samples A, B, C were prepared by adding 22.5-mL, 45-mL, and 67.5-mL respectively of DEHP to sufficient Bitcool™ to provide a total volume of 450 mL. Each mixture was vigorously shaken until the solution appeared homogeneous.

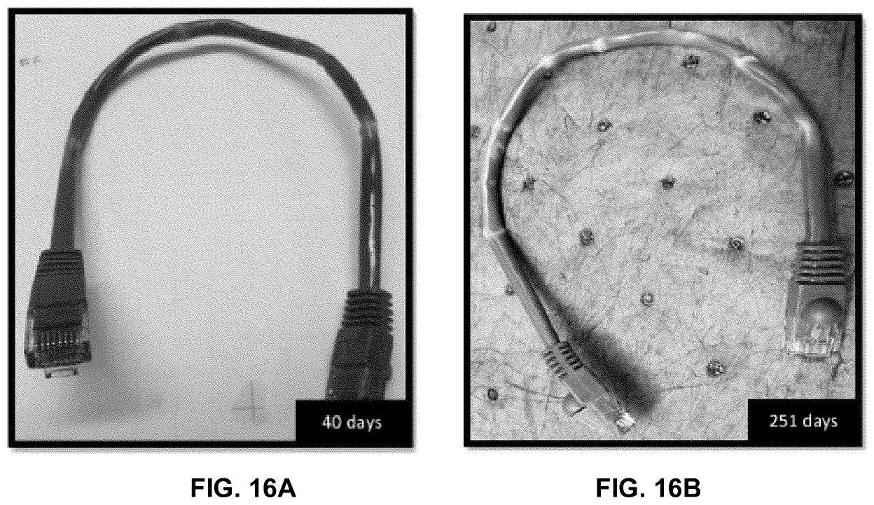

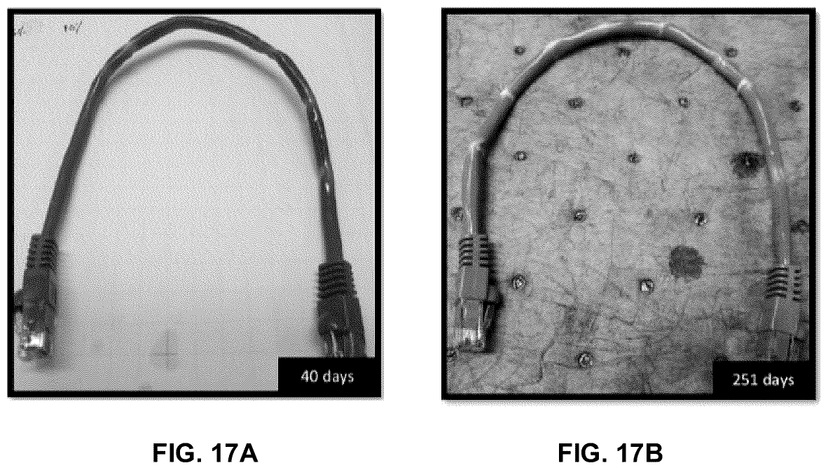

The samples were then transferred to glass jars and a test cord was submerged in each mixture before each jar was covered. Each jar was placed in a water bath between a temperature of 55-60° C. The cords were observed visually and physically examined. Photographs of the cords after immersion in Samples A, B, C, for 40 days are shown in FIGS. 16A, 17A and 18A respectively. Photographs of the cords after immersion in Samples A, B and C for 251 days are shown in FIGS. 16B, 17B and 18B respectively. Observations of these samples and the Comparison Sample (Example 3A) are listed in Table 4.

TABLE 4

| | Observations at Specified Loading of Plasticizer | | | |
|---|---|---|---|---|
| Time | Comparison | Sample A | Sample B | Sample C |
| (days) | Sample (0 v/v %) | (5.0 v/v %) | (10.0 v/v %) | (15.0 v/v %) |
| 10 | Cord is still very | Cord is still very | Cord is still very | Cord is still very |
| | flexible and easily | flexible and | flexible and | flexible and |
| | bent. No marks or | easily bent. No | easily bent. No | easily bent. No |
| | indents made | marks or indents | marks or indents | marks or |
| | when bending. | made when | made when | indents made |
| | | bending. | bending. | when bending. |
| | | | | Cord is the |
| | | | | most flexible. |
| 17 | Cord is still very | Cord is more | Cord is quite a | Cord is |
| | flexible. Bending | easily bent than | bit more flexible | extremely |
| | does not leave a | the former (the | than the blank. | flexible. No |
| | lasting impression/ | Comparison | | indents are |
| | indent. | Sample). | | made at all |
| | | | | upon bending |
| | | | | repeatedly. |
| 21 | Cord is getting a | Cord is still | Cord is still very | Cord is the |
| | bit stiff and is | relatively easy to | flexible. No white | most flexible |
| | harder to bend | bend. Some faint | marks left after | but appears |
| | than before. Faint | white marks are | bending the cord | less puffy than |
| | white marks left | visible after | repeatedly. | the other cords. |
| | after bending the | bending the | | No indents or |
| | cord. | cord. | | marks made |
| | | | | after bending. |
| 28 | Cord is stiffer and | Cord is still | Cord is still | Cord is still |
| | starting to get | easily bent and | easily bent and | easily bent and |
| | wrinkled. | there is no | there is no | there is no |
| | | wrinkling of the | wrinkling of the | wrinkling of the |
| | | cord. | cord. | cord. |
| 35 | Cord is even | Cord is a lot | Cord is slightly | Cord is still the |
| | tougher to bend, | easier to bend | easier to bend | easiest to |
| | and distinct | than the former | than the former | bend. No |
| | marks are left | (blank). Some | (5%). Some | indents/marks |
| | after bending. | distinct marks left | distinct marks | made when |
| | | when bent. | left when bent. | bent. Cord |
| | | | | looks |
| | | | | elongated. |
| 40 | Cord is very stiff | Cord is fairly stiff, | Cord is quite a | Cord appears |
| | and tough to bend | but it is much | bit easier to bend | elongated and |
| | but there is no | easier to bend | than the former | skinnier. It is |
| | cracking or tears. | than the blank. | (5%). No cracks | still the easiest |
| | Lots of marks | No cracking or | or rips are | to bend and |
| | seen, however, | tears are visible, | visible, though | there are no |
| | from bending the | though white | some markings | visible rips or |
| | cord. | markings where | are. | cracks. |
| | | bent are. | | |
| 251 | Cord is extremely | Cord is a lot | Cord is quite | Cord is still very |
| | stiff and difficult to | easier to bend | stiff but more | flexible and |
| | bend. However, | than the blank | easily bent than | easy to bend. |
| | no cracking or | but is still quite | the former two. | The easiest to |
| | tears are present. | stiff. No rips or | No rips or tears | bend of the |
| | Only more indents | tears present | present but big | bunch. Only |
| | are visible where | after bending, | indents seen | minor indents |
| | bent. | but lots of | where | visible, no |
| | | indentations | previously bent. | cracking or rips |
| | | seen. | | present. |

With Samples A and B (5.0 v/v % of DEHP and 10. 0 v/v % respectively added to the Bitcool™), the cord was slightly easier to bend with the higher loading being a bit easier. No snapping or cracks were visible after continuous bending (FIGS. 16A-B and 17A-B) with either Sample A or B.

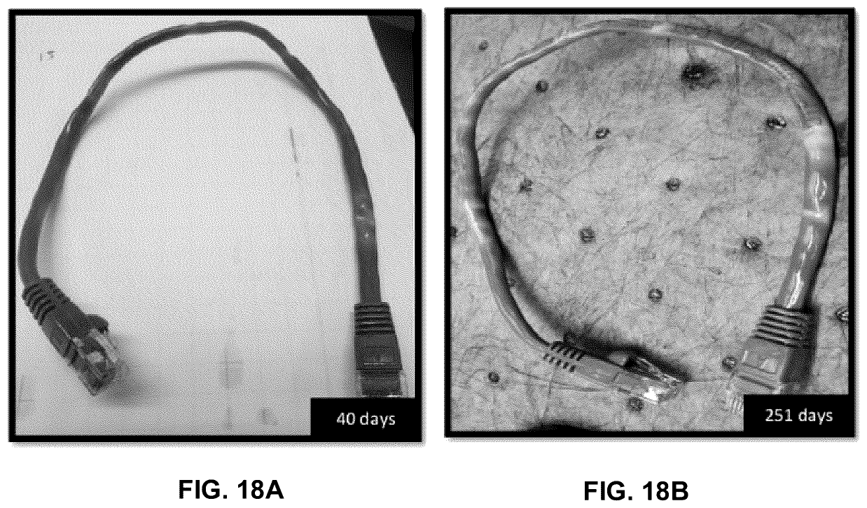

With Sample C (15.0 v/v % of DEHP added to the Bitcool™), in looking at the cord submerged in Bitcool with 15.0% DEHP, it is evident that the cord is much better maintained in comparison to samples A and B. With sample C, the is still very flexible, only has minor indentations from being bent and is still easy to bend after after being submerged for 251 days. No cracks or rips to the cord are present (FIG. 18B).

### Example 4A (Comparison)

A low-density polyethylene (PE-LD) cord was submerged in Conosol 340 at 55-60° C. for 169 days.

After an immersion period of 40 days, the cord was taken out and bent and the cord remained intact and did not have any cracks when continually bent (FIG. 19A). It also outperformed the Chevron Neutral Oil 60R (see example 2A). After 169 days, the cord was not noticeably cracked (FIG. 19B)

### Example 4B

Each low-density polyethylene cord (PE-LD) cord was submerged in a sample cooling solution containing Conosol 340 as the coolant and di(2-ethylhexyl) phthalate (DEHP) as the plasticizer at 55-60° C. for 169 days. The sample cooling solutions tested were: (A) 5.0 v/v % di(2-ethylhexyl) phthalate in Conosol 340; (B) 10.0 v/v % di(2-ethylhexyl) phthalate in Conosol 340 and (C) 15.0 v/v % di(2-ethylhexyl) phthalate in Conosol 340.

Samples A, B, C were prepared by adding 22.5-mL, 45-mL, and 67.5-mL respectively of DEHP to sufficient Conosol 340 to provide a total volume of 450 mL. Each mixture was vigorously shaken until the solution appeared homogeneous.

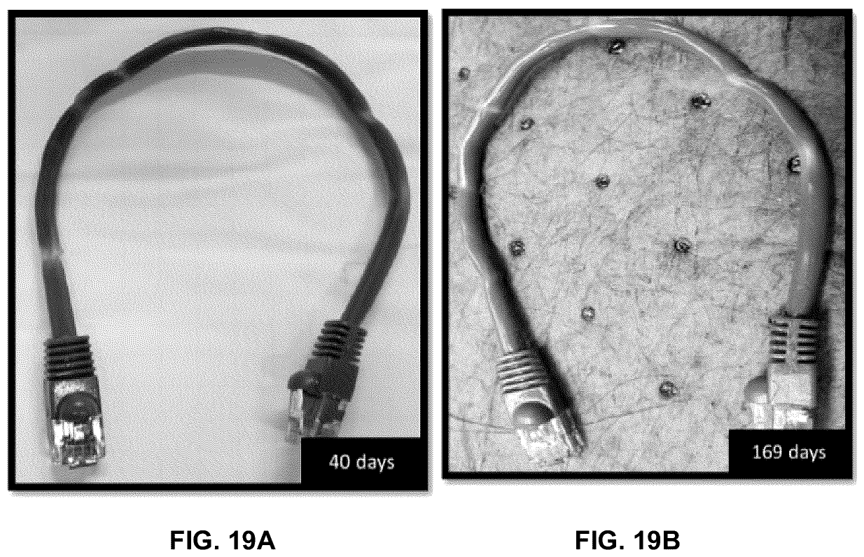

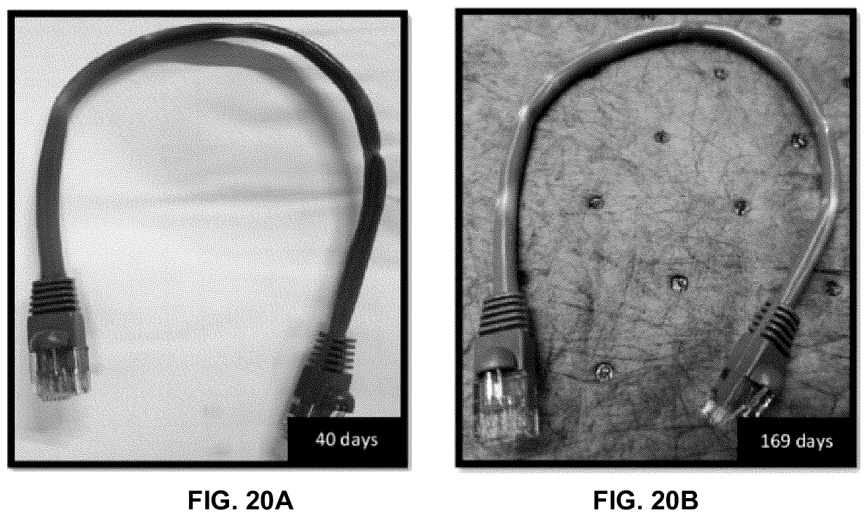

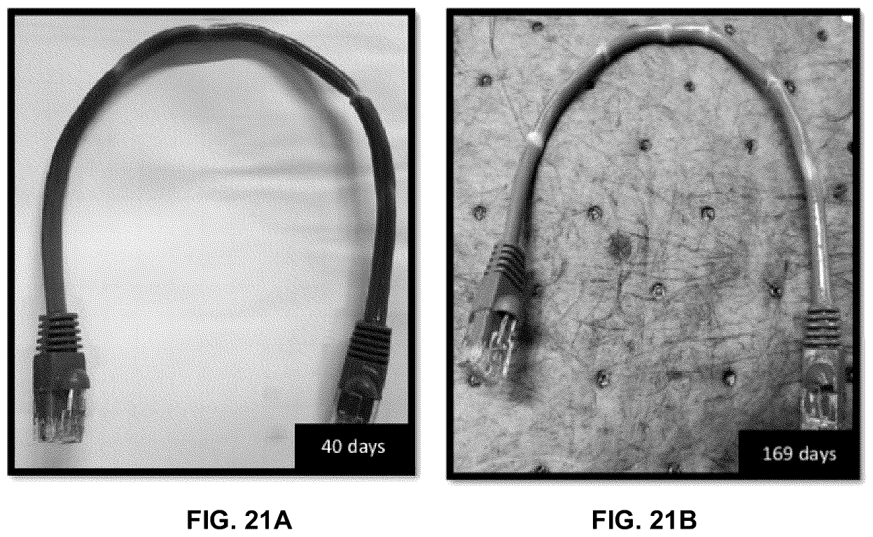

The samples were then transferred to glass jars and a test cord was submerged in each mixture before each jar was covered. Each jar was placed in a water bath between a temperature of 55-60° C. The cords were observed visually and physically examined. Photographs of the cords after immersion in Samples A, B, C, for 40 days are shown in FIGS. 20A, 21A and 22A respectively. Photographs of the cords after immersion in Samples A, B and C for 169 days are shown in FIGS. 20B, 21B and 22B respectively. Observations of these samples and the Comparison Sample (Example 4A) are listed in Table 5.

TABLE 5

| | Observations at Specified Loading of Plasticizer | | | |
|---|---|---|---|---|
| Time | Comparison | Sample A | Sample B | Sample C |
| (days) | Sample (0 v/v %) | (5.0 v/v %) | (10.0 v/v %) | (15.0 v/v %) |
| 10 | Cord is still very | Cord is flexible | Cord is flexible | Cord is |
| | flexible and easy | and easier to | and easier to | extremely |
| | to bend. No marks | bend than the | bend than the | flexible and |
| | or indents made | blank. No marks | former (5%). No | easily bent. No |
| | when bending. | or indents made | marks/indents | marks or |
| | | when bending. | made when | indents made |
| | | | bending. | when bending. |
| 17 | Cord is a bit stiffer | Cord is still very | Cord is very | Cord is very |
| | but not difficult to | flexible and is a | flexible and more | flexible and the |
| | bend. No indents | lot easier to | so than the 5%. | most flexible of |
| | or marks made. | bend than the | Easier to bend | the bunch. A lot |
| | | blank. | than the former. | easier to bend |
| | | | | than the former. |
| 21 | Cord is slightly | Cord is very | Cord is very | Cord is the |
| | stiffer but still | flexible and very | flexible and a lot | most flexible |
| | easily bent. One | easily bent. No | easier to bend | and is the |
| | slight indent seen | indents or marks | than the former | easiest to bend. |
| | after bending | made when | two. No indents/ | No indents/ |
| | cord. | bending. | marks seen. | marks seen |
| | | | | after bending. |
| 28 | Cord is still very | A lot more | Cord is more | Cord is still the |
| | flexible and easily | flexible than the | easily bent than | most flexible. A |
| | bend. Slight | blank. A white | the 5%. The cord | lot more easily |
| | indentations seen | mark seen but | looks bloated or | bent than the |
| | after bending. | no indentations | puffy. No | 5/10%. No |
| | | made after | indentations | indentations or |
| | | bending. | seen. | marks. |
| 35 | Cord is a lot stiffer | Cord is a lot | Cord is more | Cord is still |
| | and a bit harder to | more flexible | flexible and easily | extremely easy |
| | bend. More | than the blank. | bent than the 5%. | to bend. No |
| | prominent indents | Faint | No indents or | indents or |
| | seen after | impressions | impressions | impressions |
| | bending. | made on cord | made/seen. | made after |
| | | after bending. | | bending cord. |
| 40 | Cord is very stiff | Cord is more | Cord is very stiff | Cord is the |
| | and difficult to | flexible than the | and difficult to | easiest to bend |
| | bend. Lots of | blank but is very | bend. Prominent | and is the most |
| | indents made | stiff. Cord is | indents made | flexible. No |
| | after bending but | relatively difficult | after bending but | prominent |
| | no cracking or rips | to bend, and | still no cracking | indents/marks |
| | seen. | some indents | or rips. | made after |
| | | made. | | bending. |
| 169 | Cord is quite stiff | Cord is stiffer | Cord is stiffer | Cord is a bit |
| | but relatively easy | than the blank | than the former | stiff but still |
| | to bend. No rips or | but is still | and is difficult to | easily bent. No |
| | tears after being | relatively easy to | bend. No | cracks or rips |
| | bent, though | bend. Less | cracking or rips | seen, though |
| | some indentations | indentations than | after bending, | some slight |
| | seen. | the former and | though lots of | marks visible. |
| | | still no cracks or | indentation seen. | No indents |
| | | rips seen. | | after being |
| | | | | bent. |

With Samples A and B (5.0 v/v % of DEHP and 10. 0 v/v % respectively added to the Conosol 340), the cord was slightly easier to bend with the higher loading being a bit easier. No snapping or cracks were visible after continuous bending (FIGS. 20A-B and 21A-B) with either Sample A or B.

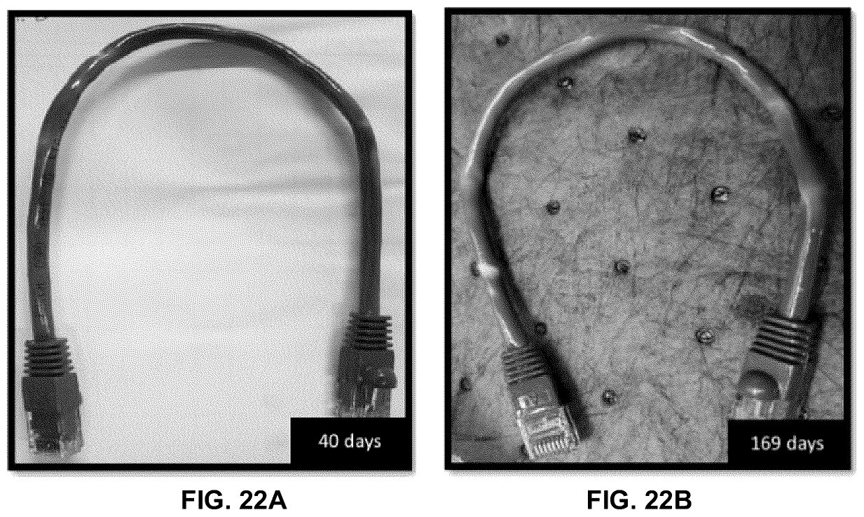

With Sample C (15.0 v/v % of DEHP added to the Conosol 340), in looking at the cord submerged in Conosol 340 with 15.0% DEHP, it is evident that the cord is much better maintained in comparison to samples A and B. With sample C, the cord does not have any indentations from being bent and is still easy to bend after being submerged for 169 days. No cracks or rips to the cord are present (FIG. 22B).

### Example 5A (Comparison)

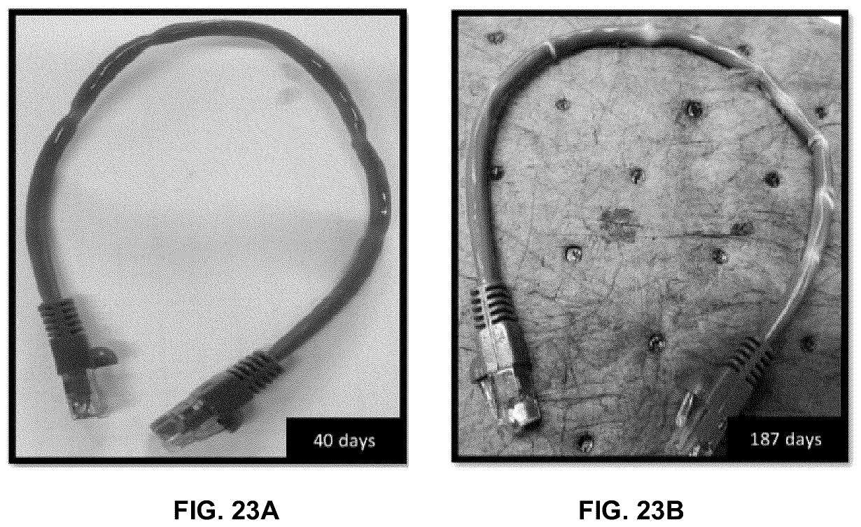

A low-density polyethylene (PE-LD) cord was submerged in Chevron Neutral Oil 60R at 55-60° C. for 187 days. The cord after 40 days can be seen in FIG. 23A and the cord after 187 days can be seen in FIG. 23B.

### Example 5B

Each low-density polyethylene cord (PE-LD) cord was submerged in a sample cooling solution containing Chevron Neutral Oil 60R as the coolant and Hexamoll Dinch (1,2-Cyclohexane dicarboxylic acid, diisononyl ester) as the plasticizer at 55-60° C. for 169 days. The sample cooling solutions tested were: (A) 5.0 v/v % Hexamoll Dinch in Chevron Neutral Oil 60R; (B) 10.0 v/v % Hexamoll Dinch in Chevron Neutral Oil 60R and (C) 15.0 v/v % Hexamoll Dinch in Chevron Neutral Oil 60R.

Samples A, B, C were prepared by adding 22.5-mL, 45-mL, and 67.5-mL respectively of Hexamoll Dinch to sufficient Chevron Neutral Oil 60R to provide a total volume of 450 mL. Each mixture was vigorously shaken until the solution appeared homogeneous.

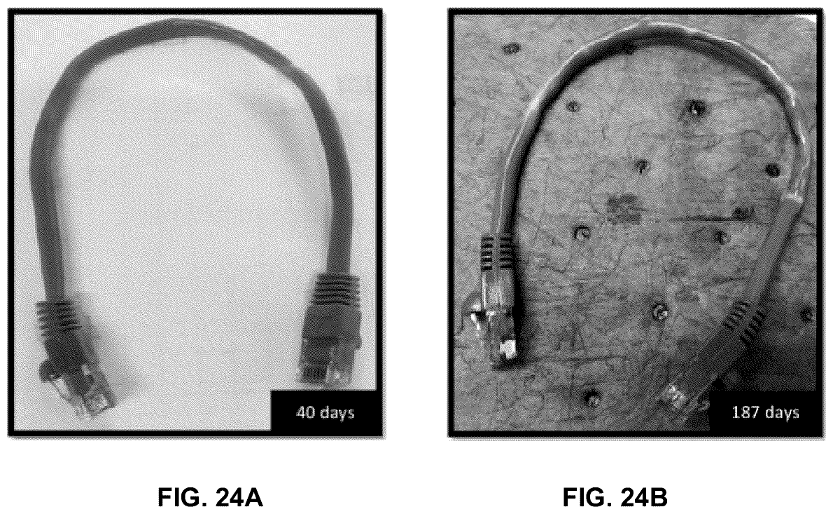

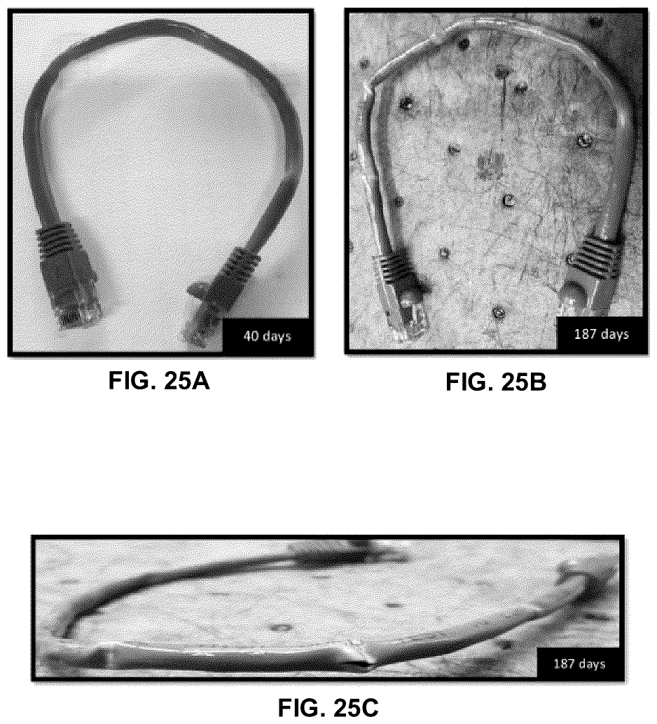

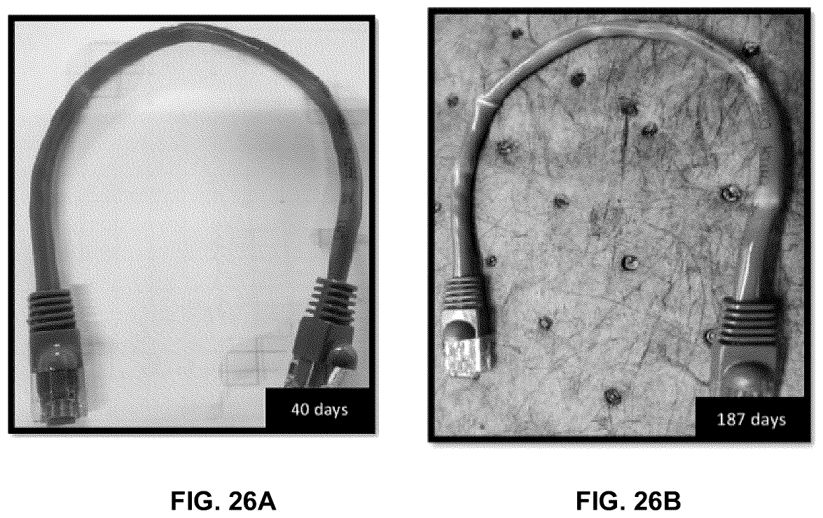

The samples were then transferred to glass jars and a test cord was submerged in each mixture before each jar was covered. Each jar was placed in a water bath between a temperature of 55-60° C. The cords were observed visually and physically examined. Photographs of the cords after immersion in Samples A, B, C, for 40 days are shown in FIGS. 24A, 25A and 26A respectively. Photographs of the cords after immersion in Samples A, B and C for 187 days are shown in FIGS. 24B, 25B-C and 26B respectively. Observations of these samples and the Comparison Sample (Example 5A) are listed in Table 6.

TABLE 6

| | Observations at Specified Loading of Plasticizer | | | |
|---|---|---|---|---|
| Time | Comparison | Sample A | Sample B | Sample C |
| (days) | Sample (0 v/v %) | (5.0 v/v %) | (10.0 v/v %) | (15.0 v/v %) |
| 10 | Cord is still very | Cord is still very | Cord is still very | Cord is the |
| | flexible and easy | flexible and easy | flexible and easy | most flexible |
| | to bend. No marks | to bend. Easier to | to bend. Easier to | and the easiest |
| | or indents made | bend than the | bend than the | to bend. Cord |
| | when bending. | former. No marks/ | former. No marks/ | looks the |
| | | indents. | indents. | thickest. No |
| | | | | marks/indents |
| 17 | Cord is still | Cord is more | Cord is more | Cord is the |
| | relatively easy to | easily bent than | easily bent than | easiest to bend |
| | bend. Minor | the former. Minor | the former. No | of the bunch. |
| | indentations seen | indentations | marks or | No marks or |
| | after bending. | seen after | indentations | indentations |
| | | bending cord. | seen after | seen after |
| | | | bending cord. | bending cord. |
| 21 | Cord is a bit more | Cord is still | Cord is still easily | Cord is still |
| | difficult to bend. | easily bent. | bent and easier | easily bent and |
| | Some more | Only minor | to bend than the | is the easiest to |
| | indentations seen | indentations | 5%. No indents/ | bend. No |
| | after bending. | seen after | marks when | indents/marks |
| | | bending cord. | bent. | when bent. |
| 28 | Cord is a bit | Cord is a bit | Cord is a bit | Cord is still the |
| | stiffer and more | stiffer, but a lot | stiffer but a bit | easiest to bend |
| | difficult to bend. | more easily bend | easier to bend | and the most |
| | More indents | than the blank. | than the 5%. | flexible. No |
| | seen after | More indents | Slight indentation | indents seen |
| | bending cord. | seen after | seen after | after bending. |
| | | bending cord. | bending. | |
| 35 | Cord is more | Cord is a bit | Cord is a lot | Cord is still |
| | difficult to bend. A | stiffer and harder | easier to bend | quite flexible |
| | lot of indents after | to bend though a | than the former | and easy to |
| | being but no | lot easier than | and is still quite | bend. A lot |
| | cracking or rips | the blank. Slight | flexible. Slight | easier to bend |
| | seen. | indentation after | indentation after | than the |
| | | bending. | bending. | former. The |
| | | | | least |
| | | | | indentation |
| | | | | seen after |
| | | | | bending. |
| 40 | Cord is very stiff | Cord is a lot | Cord is a lot | Cord is easier |
| | and much more | easier to bend | stiffer than the | to bend than |
| | difficult to bend. | than the blank. | 5% and is quite | the 10%. Some |
| | More indents and | Minimal indents | difficult to bend. | deep |
| | marks after | seen and it is still | Quite deep | indentations/ |
| | bending but no | quite flexible. | indentations seen | marks seen |
| | cracking or rips | Cord looks | after bending the | after bending |
| | seen. | thicker than the | cord. | the cord. |
| | | blank. | | |
| 187 | Cord is fairly stiff | Cord is a bit stiff | Cord is stiffer | Cord is quite |
| | and a bit difficult to | but a lot less stiff | than the 5%. | stiff but much |
| | bend. More | than the blank. It | Relatively | more flexible |
| | indents and marks | is quite easy to | difficult to bend | than the former. |
| | seen but no | bend. No tears | and the cord | Cord is easily |
| | cracking or tears. | or cracks, just | cracked when | bend with some |
| | | minimal indents. | bent and | indents but no |
| | | | exposed some | cracks. |
| | | | wires. | |

After about 40 days, the cord immersed in Sample B (10.0 v/v % of Hexamoll Dinch added to the Chevron Neutral Oil 60R) appeared to make the cord stiffer than the cord immersed in Sample A (5.0 v/v % of Hexamoll Dinch added to the Chevron Neutral Oil 60R) although the cord immersed in Sample C (15.0 v/v % of Hexamoll Dinch added to the Chevron Neutral Oil 60R appeared to make the cord more flexible than Samples A of B. At approximately 6 months, there was noticeable cracking on the cord submerged in Sample B. No noticeable cracking had been seen on the submerged cord using 10% DEHP in the same oil-Chevron Neutral Oil 60R-even after nearly ten months of being submerged in fluid (see example 2B).

### Example 6A (Comparison)

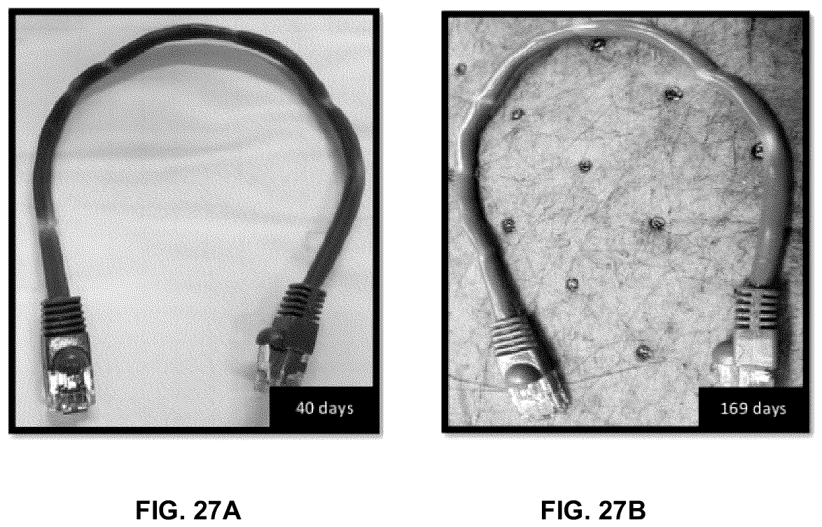

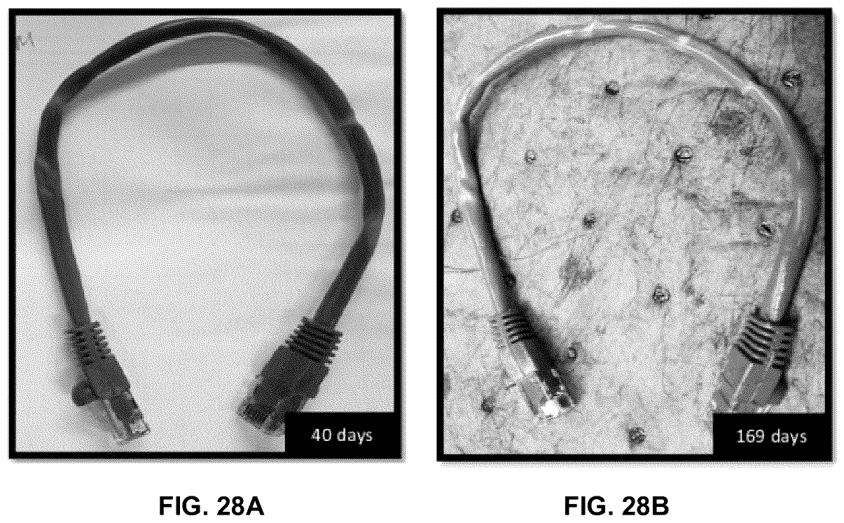

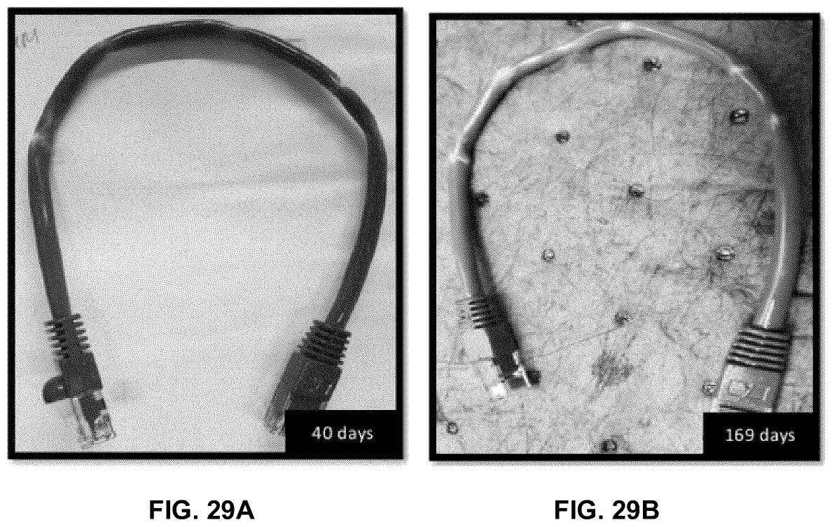

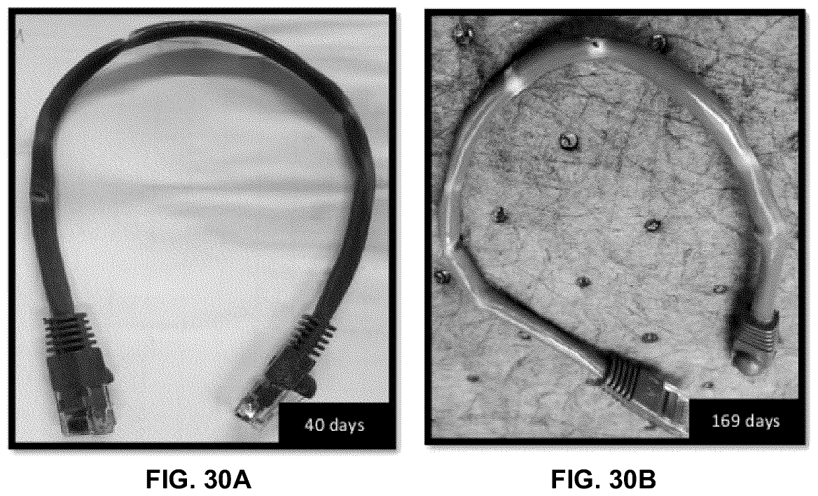

A low-density polyethylene (PE-LD) cord was submerged in Consol 340 at 55-60° C. for 169 days. The cord after 40 days can be seen in FIG. 27A and the cord after 169 days can be seen in FIG. 27B.

### Example 6B

Each low-density polyethylene cord (PE-LD) cord was submerged in a sample cooling solution containing Consol 340 as the coolant and Hexamoll Dinch (1,2-Cyclohexane dicarboxylic acid, diisononyl ester) as the plasticizer at 55-60° C. for 169 days. The sample cooling solutions tested were: (A) 5.0 v/v % Hexamoll Dinch in Consol 340; (B) 10.0 v/v % Hexamoll Dinch in Consol 340 and (C) 15.0 v/v % Hexamoll Dinch in Conosol 340.

Samples A, B, C were prepared by adding 22.5-mL, 45-mL, and 67.5-mL respectively of Hexamoll Dinch to sufficient Consol 340 to provide a total volume of 450 mL. Each mixture was vigorously shaken until the solution appeared homogeneous.

The samples were then transferred to glass jars and a test cord was submerged in each mixture before each jar was covered. Each jar was placed in a water bath between a temperature of 55-60° C. The cords were observed visually and physically examined. Photographs of the cords after immersion in Samples A, B, C, for 40 days are shown in FIGS. 24A, 25A and 26A respectively. Photographs of the cords after immersion in Samples A, B and C for 169 days are shown in FIGS. 24B, 25B and 26B respectively. Observations of these samples and the Comparison Sample (Example 6A) are listed in Table 7.

TABLE 7

| | Observations at Specified Loading of Plasticizer | | | |
|---|---|---|---|---|
| Time | Comparison | Sample A | Sample B | Sample C |
| (days) | Sample (0 v/v %) | (5.0 v/v %) | (10.0 v/v %) | (15.0 v/v %) |
| 10 | Cord is still very | Cord is still | Cord is a lot | Cord is very |
| | flexible and easy | easily bent but | easier to bend | flexible and very |
| | to bend. No marks | harder to bend | than the 5%. No | easily bent. No |
| | or indents made | than the 5% | indentations | indentations/ |
| | when bending. | DEHP. Slight | seen after | marks seen |
| | | indents seen | bending. | after bending |
| | | after bending | | cord. |
| | | cord. | | |
| 17 | Cord is a bit stiffer | Cord is a bit stiff. | Cord is easier to | Cord is still |
| | but not difficult to | Easier to bend | bend than the | easily bent and |
| | bend. No indents | than the blank | 5% and is still | much easier to |
| | or marks made. | but more difficult | very flexible. | bend than the |
| | | to bend than the | | former. Cord is |
| | | 5% DEHP. | | very flexible. |
| 21 | Cord is slightly | Cord is still | Cord is a lot | Cord is a lot |
| | stiffer but still | easily bent and | easier to bend | easier to bend |
| | easily bent. One | is quite flexible. | than the former. | than the 5%. |
| | slight indent seen | Not as easy to | Cord is flexible | Cord is the |
| | after bending | bend as the 5% | and no | most flexible |
| | cord. | DEHP. One | indentations | and no |
| | | indent seen after | seen after | indentations or |
| | | bending cord. | bending cord. | marks visible. |
| 28 | Cord is still very | Cord is slightly | Cord is more | Cord is very |
| | flexible and easily | stiff but still easily | easily bent than | flexible and the |
| | bend. Slight | bent. Not as | the 5%. No | easiest to bend. |
| | indentations seen | bendable as the | indents or | No indentations |
| | after bending. | 5% DEHP. | marks after | or marks after |
| | | | bending. | bending. |
| 35 | Cord is a lot stiffer | Cord is stiff and | Cord is easier to | Cord is very |
| | and a bit harder to | relatively difficult | bend than the | flexible and |
| | bend. More | to bend. Some | former. Slight | easily bent. |
| | prominent indents | impressions and | impressions but | Slight |
| | seen after | indents seen | no indents after | impressions |
| | bending. | after bending. | bending. | but no indents |
| | | | | after bending. |
| 40 | Cord is very stiff | Cord is a bit | Cord is the | Cord is a bit |
| | and difficult to | easier to bend | easiest to bend | less flexible |
| | bend. Lots of | than the former. | and a lot more | than the 10% |
| | indents made | Some | flexible than the | Hexamoll |
| | after bending but | impressions/ | 5%. Slight | Dinch. Some |
| | no cracking or rips | indents seen | impressions | indents seen |
| | seen. | after bending | made after | after bending |
| | | cord. | bending cord. | the cord. |
| 169 | Cord is quite stiff | Cord is quite stiff | Cord is a bit stiff | Cord is a bit stiff |
| | but relatively easy | and relatively | but a lot easier to | but a lot easier |
| | to bend. No rips or | hard to bend. | bend than the | to bend than |
| | tears after being | More indents | 5% Hexamoll | the 5% |
| | bent, though | seen after | Dinch. A few | Hexamoll |
| | some indentations | bending but no | indents seen but | Dinch. A few |
| | seen. | cracking or tears | no cracking/ | indents seen |
| | | visible. | tears is visible. | but no cracking/ |
| | | | | tears is visible. |

After about 40 days, the cord immersed in Sample C (15.0 v/v % of Hexamoll Dinch added to the Consol 340) appeared to make the cord stiffer than the cord immersed in Sample B (10.0 v/v % of Hexamoll Dinch added to the Chevron Neutral Oil 60R). No noticeable cracking had been seen on the submerged cord using 10% DEHP in the same oil-Consol 340—even being submerged in the fluid for the same amount of time (see example 2B).

It was observed that as the amount of DEHP added to either DRILLSOL Plus or Chevron Neutral Oil 60R was increased, the resulting cords became progressively more resistant to deterioration and cracking. In both examples, the highest concentration of DEHP tested produced the best results. Based on these observations, through visual inspection and manual testing, it is suspected that that the plasticizer is causing these results. It is expected that higher concentrations of DEHP may improve the resistance of the cords to deterioration and cracking.

The term “substantially free” refers to a composition in which a particular constituent or moiety is present in an amount that has no material effect on the overall composition. In some embodiments, “substantially free” may refer to a composition in which the particular constituent or moiety is present in the composition in an amount of less than about 10 wt % or less than about 5 wt %, or less than about 4 wt %, or less than about 3 wt % or less than about 2 wt % or less than about 1 wt %, or less than about 0.5 wt %, or less than about 0.1 wt %, or less than about 0.05 wt %, or even less than about 0.01 wt % based on the total weight of the composition, or that no amount of that particular constituent or moiety is present in the respective composition.

The term “wt %” means weight percent.

The term “about” as used herein can allow for a degree of variability in a value or range, for example, within 5% of a stated value or of a stated limit of a range.

When introducing elements of the present invention or the embodiments thereof, the articles “a,” “an,” “the,” and “said” are intended to mean that there are one or more of the elements. The terms “comprising,” “including,” and “having” are intended to be inclusive and mean that there may be additional elements other than the listed elements.

Of course, the above described embodiments are intended to be illustrative only and in no way limiting. The described embodiments of carrying out the invention are susceptible to many modifications of form, arrangement of parts, details, and order of operation. The invention, therefore, is intended to encompass all such modifications within its scope.

1.-21. (canceled)

22. A cooling fluid comprising:
a coolant for immersion cooling an object, the object comprising a pre-plasticized surface, wherein the coolant is a liquid coolant; and
a plasticizer dispersed in the coolant, wherein the cooling fluid is a source of the plasticizer for supplying plasticizer into the object when the object is in contact with the cooling fluid.

23. The cooling fluid of claim 22, wherein the weight ratio of the plasticizer in the cooling fluid to the coolant is at least 0.1.

24. The cooling fluid of claim 22, wherein the weight ratio of the plasticizer in the cooling fluid to the coolant is at least 0.15.

25. The cooling fluid of claim 22, wherein the weight ratio of the plasticizer in the cooling fluid to the coolant is at least 0.2.

26. The cooling fluid of claim 22, wherein the weight ratio of the plasticizer in the cooling fluid to the coolant is from 0.005 to 0.2.

27. The cooling fluid of claim 22, wherein the plasticizer in the cooling fluid is the same as a plasticizer in the pre-plasticized surface of the object.

28. The cooling fluid of claim 27, wherein a concentration of the plasticizer in the cooling fluid is the same or higher than a concentration of the plasticizer in the pre-plasticized surface of the object.

29. The cooling fluid of claim 22, wherein the plasticizer in the cooling fluid comprises a low molecular weight ortho-phthalate, a high molecular weight ortho-phthalate, a terephthalate, a trimellitate, an aliphatic, a benzoate, a phosphate, or a polymeric plasticizer.

30. The cooling fluid of claim 29, wherein the low molecular weight ortho-phthalate comprises butyl benzyl phthalate (BBP), dimethyl phthalate (DMP) diethyl phthalate (DEP), diisobutyl phthalate (DIBP), dihexyl phthalate (DHP), di-n-butyl phthalate (DBP), dicyclohexyl phthalate (DCHP), di(2-ethylhexyl) phthalate (DEHP), 1,2-cyclohexane dicarboxylic acid diisononyl ester (DINCH) or di(2-propylheptyl) phthalate (DPHP).

31. The cooling fluid of claim 22, wherein a concentration of the plasticizer in the cooling fluid is 5 wt % to 15 wt % based on a total weight of the cooling fluid.

32. The cooling fluid of claim 22, wherein the coolant comprises an oil.

33. The cooling fluid of claim 22, wherein the coolant has a density of between 0.800 and 1.100 kg/L at 15° C.

34. A cooling system comprising:
a container comprising a chamber for receiving therein an object to be cooled;
the cooling fluid of claim 22 in the chamber for immersing the object in the cooling fluid.

35. The system of claim 34, wherein the object comprises a computing device.

36. A method of cooling an object comprising a pre-plasticized surface, the method comprising:
immersing the object in the cooling fluid of claim 22 within a container, wherein the pre-plasticized surface is in contact with the cooling fluid.

37. The method of claim 36, wherein the pre-plasticized surface of the object comprises a plasticized polymer.

38. The method of claim 36, wherein the object comprises a computing device.

39. The method of claim 38, wherein the computing device is immersion cooled in the cooling fluid at a temperature of at least 50° C. for at least 30 days.

40. A method of forming a cooling fluid for immersion cooling an object, wherein the object comprises a plasticized polymer, the method comprising:
selecting and providing a liquid coolant suitable for immersion cooling the object;
mixing the liquid coolant with a plasticizer to form a liquid mixture, wherein the liquid mixture is a source of the plasticizer for supplying plasticizer into the object when the object is immersed in the liquid mixture within a container.
